(19) United States
(12) Patent Application Publication
(10) Pub. No.: US 2025/0293209 A1
(43) Pub. Date: Sep. 18, 2025

(54) CHIP PACKAGING METHOD AND CHIP PACKAGING STRUCTURE

(71) Applicant: TONGFU MICROELECTRONICS CO., LTD., Nantong (CN)

(72) Inventors: Lei SHI, Nantong (CN); Xin XIA, Nantong (CN); Yujuan TAO, Nantong (CN)

(21) Appl. No.: 19/223,733

(22) Filed: May 30, 2025

Related U.S. Application Data
(63) Continuation of application No. PCT/CN2023/136626, filed on Dec. 6, 2023.

(30) Foreign Application Priority Data
Dec. 6, 2022 (CN) 202211553696.1
Dec. 6, 2022 (CN) 202211553758.9
Dec. 6, 2022 (CN) 202211554549.6
Dec. 6, 2022 (CN) 202211555058.3
Dec. 6, 2022 (CN) 202211555419.4
Dec. 6, 2022 (CN) 202211555903.7
Dec. 6, 2022 (CN) 202211556459.0
Dec. 6, 2022 (CN) 202211556609.8
Dec. 6, 2022 (CN) 202211557780.0
Dec. 6, 2022 (CN) 202211557781.5
Dec. 6, 2022 (CN) 202211557789.1
Dec. 6, 2022 (CN) 202211557809.5
Dec. 6, 2022 (CN) 202211558289.X
Dec. 6, 2022 (CN) 202211558474.9
Dec. 6, 2022 (CN) 202211558476.8
Dec. 6, 2022 (CN) 202211578865.7

(51) Int. Cl. H01L 25/065; H01L 21/48; H01L 21/56; H01L 21/683; H01L 21/78; H01L 23/00; H01L 23/14; H01L 23/29; H01L 23/31; H01L 23/538

(52) U.S. Cl. CPC H01L 25/0655; H01L 21/4846; H01L 21/568; H01L 21/6835; H01L 21/78; H01L 23/147; H01L 23/293; H01L 23/3128; H01L 23/3135; H01L 23/5385; H01L 23/5386; H01L 24/08; H01L 24/80; H01L 24/96; H01L 24/97; H01L 24/16; H01L 24/81; H01L 2224/08225; H01L 2224/16225; H01L 2224/80895; H01L 2224/80896; H01L 2224/81203; H01L 2224/96; H01L 2224/97; H01L 2924/1815

(57) ABSTRACT

A chip packaging method and a chip packaging structure are provided. The method includes: providing a carrier and wafers, where at least one wafer is different from others; cutting each wafer to form chips; selecting target chips from the chips to form chipsets, and fixing functional surfaces of the chipsets to the carrier; forming a first plastic encapsulation layer on a side of the chipsets away from the carrier and removing the carrier; forming silicon interposer plates and bonding the silicon interposer plates to the chipsets; cutting the silicon interposer plates and the chipsets to form chip micro-modules each of which includes one chipset; fixing a side of the silicon interposer plates to the carrier and forming a second plastic encapsulation layer on a side of the chip micro-modules away from the carrier; and removing the carrier and cutting the second plastic encapsulation layer, to form independent packaging structures.

### CROSS-REFERENCE TO RELATED APPLICATION

This application is a continuation application of PCT Patent Application No. PCT/CN2023/136626, filed on Dec. 6, 2023, which claims the priority of Chinese Patent Application Nos. CN202211555058.3, CN202211555419.4, CN202211553696.1, CN202211558289.X, CN202211557781.5, CN202211556609.8, CN202211557809.5, CN202211558476.8, CN202211578865.7, CN202211555903.7, CN202211556459.0, CN202211557789.1, CN202211557780.0, CN202211558474.9, CN202211553758.9, and CN202211554549.6, filed on Dec. 6, 2022, the contents of all of which are incorporated herein by reference in their entirety.

### TECHNICAL FIELD

The present disclosure generally relates to the field of semiconductor packaging technology and, more particularly, relates to a chip packaging method and a chip packaging structure.

### BACKGROUND

In 2.5D packaging technology, a silicon interposer is mainly an intermediate structure connected between a chip and a substrate to amplify and transmit signals from the chip to the substrate. The chip package becomes thinner and thinner, and a plurality of chips may be connected to the silicon interposer. Therefore, when chips are installed on a silicon interposer and the silicon interposer is thinned, the silicon interposer is prone to warp or even rupture.

Therefore, it is a problem to be solved to provide a chip packaging method and a chip packaging structure to at least partially alleviate the above problems.

### SUMMARY

One aspect of the present disclosure provides a chip packaging method. The method includes: providing a carrier and a plurality of wafers, wherein at least one of the plurality of wafers is different from other wafers of the plurality of wafers; cutting each of the plurality of wafers respectively, to form a plurality of chips; selecting a plurality of target chips from the plurality of chips to form a chipsets, and fixing functional surfaces of the chipsets to the carrier; forming a first plastic encapsulation layer on a side of the chipsets away from the carrier and removing the carrier; forming silicon interposer plates and bonding the silicon interposer plates to the chipsets; cutting the silicon interposer plates and the chipsets after bonding to form a plurality of chip micro-modules, wherein each of the plurality of chip micro-modules includes one of the chipsets; fixing a side of the silicon interposer plates in the plurality of chip micro-modules to the carrier and forming a second plastic encapsulation layer on a side of the plurality of chip micro-modules away from the carrier; and removing the carrier and cutting the second plastic encapsulation layer, to form independent packaging structures.

Another aspect of the present disclosure provides a chip packaging method. The method includes: providing a carrier, a plurality of silicon wafers, and a plurality of chips; forming conductive connection structures on the plurality of silicon wafers respectively to form a plurality of silicon interposer plates; where the conductive connection structures on at least one of the plurality of silicon interposer plates is different from the conductive connection structures on others of the plurality of silicon interposer plates; cutting each of the plurality of silicon interposer plates respectively to obtain a plurality of silicon interposer sub-plates; selecting a plurality of target silicon interposer sub-plates from the plurality of silicon interposer sub-plates according to preset packaging requirements, and fixing the plurality of target silicon interposer sub-plate to the carrier; forming a first plastic encapsulation layer on a side of the plurality of silicon interposer sub-plates away from the carrier; and interconnecting the plurality of chips to the plurality of target silicon interposer sub-plates respectively.

One aspect of the present disclosure provides a chip packaging structure. The structure includes: a plurality of chips, a silicon interposer, a bonding structure, a first plastic encapsulation layer, and a second plastic encapsulation layer. The plurality of chips is bonded and connected to the silicon interposer through the bonding structure; the first plastic encapsulation layer wraps the plurality of chips; and the second plastic encapsulation layer wraps the silicon interposer, the plurality of chips and the first plastic encapsulation layer.

### BRIEF DESCRIPTION OF THE DRAWINGS

The following drawings are merely examples for illustrative purposes according to various disclosed embodiments and are not intended to limit the scope of the present disclosure.

FIG. 1 illustrates an exemplary chip packaging method according to various disclosed embodiments of the present disclosure.

FIG. 2 to FIG. 16 illustrates structures corresponding to different stages of an exemplary chip packaging method according to various disclosed embodiments of the present disclosure.

FIG. 16 illustrates a cross-sectional view of an exemplary chip packaging structure according to various disclosed embodiments of the present disclosure.

FIG. 17 illustrates a flow chart of another chip packaging method according to various embodiments of the present disclosure;

FIG. 18 illustrates blind holes formed on a silicon wafer according to various embodiments of the present disclosure;

FIG. 19 illustrates a first silicon interposer plate and first conductive connection structures according to various embodiments of the present disclosure;

FIG. 20 and FIG. 21 illustrate a packaging method of a second silicon interposer plate and second conductive connection structures according to various embodiments of the present disclosure;

FIG. 22 to FIG. 24 illustrate a packaging method of a third silicon interposer plate and third conductive connection structures according to various embodiments of the present disclosure;

FIG. 25 to FIG. 27 illustrate a packaging method of a fourth silicon interposer plate and fourth conductive connection structures according to various embodiments of the present disclosure;

FIG. 28 illustrates an exemplary first silicon interposer sub-plate according to various embodiments of the present disclosure;

FIG. 29 illustrates an exemplary second silicon interposer sub-plate according to various embodiments of the present disclosure;

FIG. 30 illustrates an exemplary third silicon interposer sub-plate according to various embodiments of the present disclosure;

FIG. 31 illustrates an exemplary fourth silicon interposer sub-plate according to various embodiments of the present disclosure;

FIG. 32 to FIG. 36 illustrates structures corresponding to different stages of an exemplary chip packaging method according to various embodiments of the present disclosure;

FIG. 37 to FIG. 41 illustrates structures corresponding to different stages of an exemplary chip packaging method according to various embodiments of the present disclosure;

FIG. 42 to FIG. 47 illustrates structures corresponding to different stages of an exemplary chip packaging method according to various embodiments of the present disclosure;

FIG. 48 to FIG. 52 illustrates structures corresponding to different stages of an exemplary chip packaging method according to various embodiments of the present disclosure;

FIG. 53 to FIG. 57 illustrates structures corresponding to different stages of an exemplary chip packaging method according to various embodiments of the present disclosure;

FIG. 58 illustrates another exemplary chip packaging structure according to various embodiments of the present disclosure;

FIG. 59 illustrates a schematic structure of conductive connection structures according to various embodiments of the present disclosure;

FIG. 60 illustrates another schematic structure of conductive connection structures according to various embodiments of the present disclosure;

FIG. 61 illustrates another schematic structure of conductive connection structures according to various embodiments of the present disclosure;

FIG. 62 illustrates another exemplary chip packaging structure according to various embodiments of the present disclosure;

FIG. 63 illustrates another exemplary chip packaging structure according to various embodiments of the present disclosure;

FIG. 64 illustrates another exemplary chip packaging structure according to various embodiments of the present disclosure;

FIG. 65 illustrates another exemplary chip packaging structure according to various embodiments of the present disclosure;

FIG. 66 illustrates another exemplary chip packaging structure according to various embodiments of the present disclosure;

FIG. 67 illustrates another exemplary chip packaging structure according to various embodiments of the present disclosure;

FIG. 68 illustrates another exemplary chip packaging structure according to various embodiments of the present disclosure; and

FIG. 69 illustrates another exemplary chip packaging structure according to various embodiments of the present disclosure.

### DETAILED DESCRIPTION

Reference will now be made in detail to exemplary embodiments of the disclosure, which are illustrated in the accompanying drawings. Wherever possible, the same reference numbers will be used throughout the drawings to refer to the same or like parts.

It should be noted that “surface” or “upper” in this specification are used to describe the relative positional relationship in space, and are not limited to whether components are in direct contact.

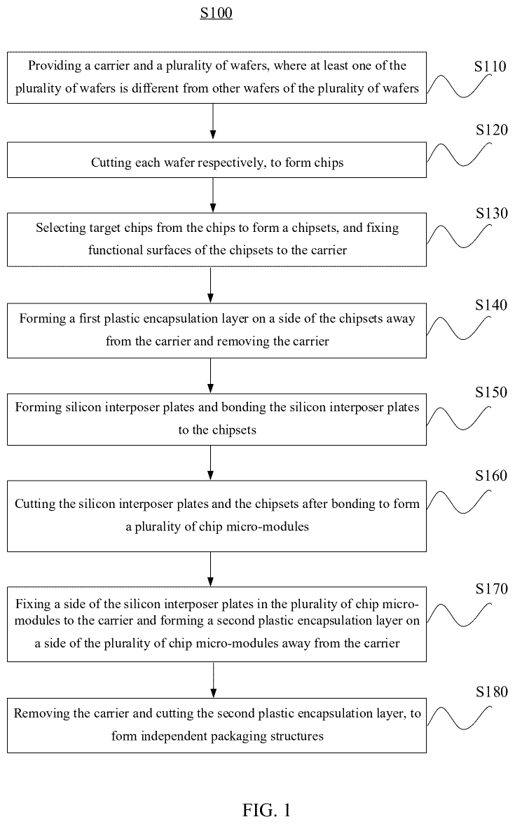

One embodiment of the present disclosure provides a chip packaging method. As shown in FIG. 1, the method S100 may include S110 to S150.

In S110, a substrate and a plurality of wafers may be provided. At least one of the plurality of wafers may be different from other wafers of the plurality of wafers.

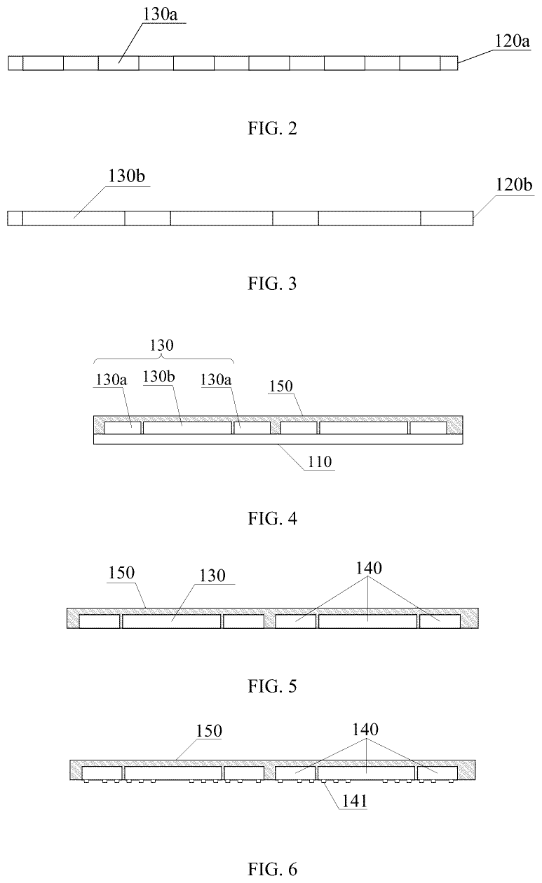

As shown in FIG. 2 to FIG. 4, in one embodiment, a carrier 110 may be provided. The carrier 110 may be made of a material including glass, silicon wafers or metals. The plurality of wafers may be provided. At least one of the plurality of wafers may be different from other wafers of the plurality of wafers. That is, the plurality of wafers may have different types. The present disclosure has no limit on the number of the plurality of wafers.

In S120, each of the plurality of wafers may be cut respectively, to form a plurality of chips.

In one embodiment, the plurality of chips may be a plurality of heterogeneous chips.

As shown in FIG. 2 to FIG. 4, in one embodiment, each of the plurality of wafers may be cut respectively, to form the plurality of chips 130. In one embodiment, a first wafer 120a may be cut to form a plurality of first chips 130a as shown in FIG. 2, a second wafer 120b may be cut to form a plurality of second chips 130b. Sizes of the plurality of second chips 130b may be larger than sizes of the plurality of first chips 130a, and the plurality of second chips 130b and the plurality of first chips 130a may be heterogeneous chips. That is, the plurality of heterogeneous chips 130 may be obtained. The present embodiment where two wafers are cut is used as an example only to illustrate the present disclosure, but does not limit the scope of the present disclosure. In some other embodiments, three, four, or more wafers may be cut.

In S130, a plurality of target chips may be selected from the plurality of chips to form chipsets, and functional surfaces of the chipsets may be fixed on the carrier.

In one embodiment, as shown in FIG. 4 and FIG. 5, the plurality of target chips may be selected from the plurality of chips 130 to form the chipsets 140, and the functional surface of the chipsets 140 may be fixed to the carrier 110. As shown in FIG. 4 and FIG. 5, in one embodiment, two first chips 130a and one second chip 130b may be selected from the plurality of chips 130 as the plurality of target chips. The second chip 130b may be disposed in the middle, and the two first chips 130a may be disposed at two sides of the second chip 130 respectively, to form the chipsets 140. Of course, other reorganization methods may be also possible, which are not specifically limited in the present disclosure and may be selected according to actual needs.

The plurality of target chips may be reorganized to form the chipsets 140, and the functional surface of the plurality of chipsets 140 may be fixed on the carrier 110 through an adhesive layer.

In S140, a first plastic encapsulation layer may be formed on a side of the plurality of chipsets away from the carrier, and then the carrier may be removed.

In one embodiment, as shown in FIG. 4, the first plastic encapsulation layer 150 may be formed on the side of the chipsets 140 away from the carrier 110. That is, the first plastic encapsulation layer 150 may be formed on non-functional surfaces of the chipsets 140. The first plastic encapsulation layer 150 may wrap the chipsets 140, to fix the chipsets 140 and form an integral plastic package for subsequent packaging and protecting the chipsets 140.

In one embodiment, the first plastic encapsulation layer 150 may be formed using a compression molding process, a transfer molding process, a liquid sealing molding process, a vacuum lamination process, or a spin coating process, which is not specifically limited in this embodiment. The first plastic encapsulation layer 150 may be made of a material including polyimide, silicone, epoxy resin, or similar materials.

As shown in FIG. 5, after forming the first plastic encapsulation layer 150, the carrier 110 may be removed. That is, the chipsets 140 may be separated from the carrier 110. The chipsets 140 may be separated from the carrier 110 by a thermal separation method, a laser separation method, an ultra-violet separation method, a mechanical separation method, or other separation methods, which may be selected according to actual needs.

In S150, a silicon interposer plate may be formed and the chipsets may be bonded to the silicon interposer plate.

In one embodiment, the silicon interposer plate 160 may be formed and the chipsets 140 may be bonded to the silicon interposer plate.

In one embodiment, in S150, the silicon interposer plate may be formed by following processes.

First, a silicon wafer may be provided and a plurality of blind holes distributed at intervals may be formed on a front surface of the silicon wafer.

In one embodiment as shown in FIG. 8 and FIG. 9, the silicon wafer 161 may be provided, and the plurality of blind holes distributed at intervals (not shown in the figure) may be formed on the front surface of the silicon wafer 161 through photolithography or etching processes. Subsequently, an insulating layer, a diffusion barrier layer and a seed layer may be deposited on sidewalls of the plurality of blind holes (the insulating layer, the diffusion barrier layer and the seed layer are not shown in the figure).

In various embodiments, the plurality of blind holes may be distributed at equal intervals or at unequal intervals, which may be selected according to actual needs. In one embodiment, the plurality of blind holes may be distributed at equal intervals, and the density of the interval distribution may be selected according to actual needs.

Subsequently, conductive materials may be filled in the plurality of blind holes to form a plurality of conductive connection structures.

In one embodiment, as shown in FIG. 9, the plurality of blind holes may be filled with conductive materials through a plating process, and a surface of the plurality of blind holes may be planarized through a chemical mechanical polishing process, to form the plurality of conductive connection structures 162. The plurality of conductive connection structures 162 may be used to achieve vertically electrical connections, to reduce the packaging height.

Subsequently, a first redistribution layer may be formed on the front side of the silicon wafer to form the silicon interposer plate. The first redistribution layer may be electrically connected to the plurality of conductive connection structures.

In one embodiment, as shown in FIG. 10, the first redistribution layer 163 may be formed on the front surface of the silicon wafer161. That is, the first redistribution layer 163 may be formed on the plurality of conductive connection structures 162.

In one embodiment, the first redistribution layer 163 may include a dielectric layer (not shown in the figure) and a metal layer (not shown in the figure) disposed on the dielectric layer. A chemical vapor deposition process or a physical vapor deposition process may be used to coat the surface of the silicon wafer 161 with the plurality of conductive connection structures 162 to form the dielectric layer, and a photolithography process may be used to pattern the dielectric layer to form a plurality of openings in the dielectric layer. Subsequently, the metal layer may be formed on the patterned dielectric layer using processes such as chemical vapor deposition, evaporation, sputtering, electroplating or chemical plating.

The dielectric layer may be made of a material including polyimide (PI), polybenzoxazole (PBO), etc., and the coating method may be usually chip spin coating, which is not specifically limited in this embodiment. The metal layer may be made of a material including titanium, copper, or other metal materials, which is not specifically limited in this embodiment.

In one embodiment, in S150, after forming the silicon interposer plate, the silicon interposer plate may be bonded with the chipsets through following processes.

First metal pads and a first passivation layer may be sequentially formed on the functional surfaces of the chipsets and the first plastic encapsulation layer.

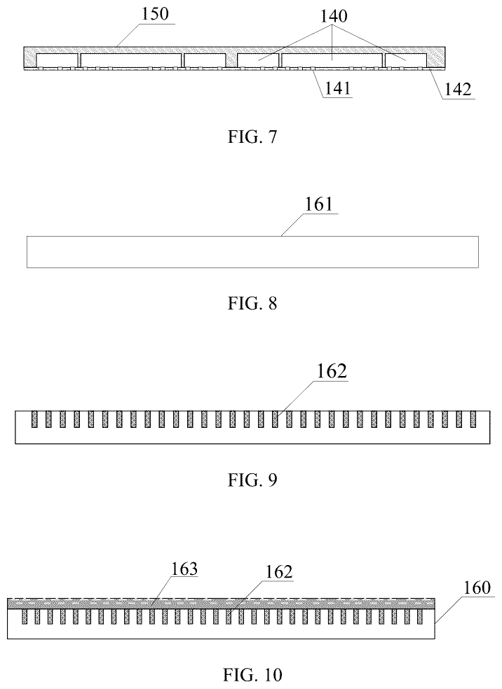

In one embodiment, as shown in FIGS. 6 and 7, after the first plastic encapsulation layer 150 is formed on the non-functional surfaces of the chipsets 140, the carrier 110 may be removed, and the first metal pads 141 and first passivation layer 142 may be sequentially formed on the functional surfaces of the chipsets and the first plastic encapsulation layer respectively.

As shown in FIG. 6, in one embodiment, the first metal pads 141 may be formed through processes such as electroplating or sputtering. The first metal pads 141 may be made of a material including metal copper or other metal materials, and there is no specific limitation in this embodiment.

As shown in FIG. 7, in one embodiment, a chemical vapor deposition process or a physical vapor deposition process may be used to form the first passivation layer 142 on the first metal pads 141. Then, openings may be formed at position in the first passivation layer 142 where the first passivation layer 142 covers the first metal pads 141 through photolithography or etching processes, to expose the surfaces of the first metal pads 141. The surface of the first passivation layer 142 may be flush with the surfaces of the first metal pads 141.

The first passivation layer 142 may be a silicon dioxide layer or a silicon nitride layer, or may be made of other materials that can play a passivation role, which is not specifically limited in this embodiment.

Subsequently, second metal pads and a second passivation layer may be formed sequentially on the first redistribution layer.

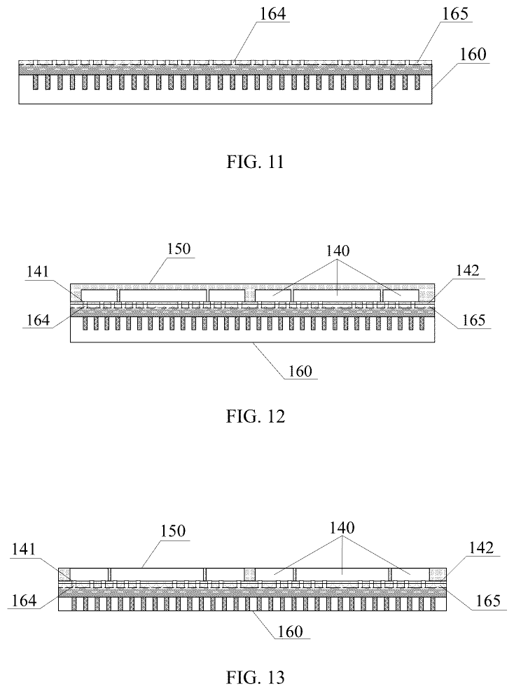

In one embodiment, as shown in FIG. 11, in one embodiment, the second metal pads 164 may be formed through processes such as electroplating or sputtering, on the first redistribution layer 163. The second metal pads 164 may be made of a material including metal copper or other metal materials, and there is no specific limitation in this embodiment. The positions of the second metal pads 164 may correspond to the positions of the first metal pads 141.

In one embodiment, a chemical vapor deposition process or a physical vapor deposition process may be used to form the second passivation layer 165 on the second metal pads 164. Then, openings may be formed at position in the second passivation layer 165 where the second passivation layer 165 covers the second metal pads 164 through photolithography or etching processes, to expose the surfaces of the second metal pads 164. The surface of the second passivation layer 165 may be flush with the surfaces of the second metal pads 164.

The second passivation layer 165 may be a silicon dioxide layer or a silicon nitride layer, or may be made of other materials that can play a passivation role, which is not specifically limited in this embodiment.

Subsequently, the second metal pads may be bonded to the first metal pads, and the second passivation layer may be bonded to the first passivation layer.

In one embodiment, as shown in FIG. 12, the first passivation layer 142 and the second passivation layer 165 may be first aligned, and the first passivation layer 142 and the second passivation layer 165 may be press together through high temperature for connection. Then, the first metal pads 141 may be aligned with its corresponding second metal pads 164, and the connection may be achieved through high-temperature press and the thermal expansion of copper.

In this embodiment, the vertical interconnection of the silicon interposer plate 160 and the chipsets 140 may be achieved through a hybrid bonding process. Through the hybrid bonding process, the packaging height may be reduced to the greatest extent and ultra-thin packaging may be achieved. Of course, in other embodiments, the vertical interconnection of the silicon interposer plate 160 and the chipsets 140 may be achieved through other bonding processes, such as thermocompression bonding or flip-chip processes, which are not limited in the present disclosure.

In some embodiments, after bonding the silicon interposer plate and the chipsets, the method may further include:
thinning a side of the first plastic encapsulation layer away from the silicon interposer plate, to expose the non-functional surfaces of the chipsets.

As shown in FIG. 13, in one embodiment, the side of the first plastic encapsulation layer 150 away from the silicon interposer plate 160 by grinding or chemical mechanical polishing processes, to expose the non-functional surfaces of the chipsets 140. The non-functional surfaces of the chipsets 140 may be flush, for subsequent packaging.

In one embodiment, a side of the silicon interposer plate away from the chipsets may be thinned to expose the plurality of conductive connection structures.

As shown in FIG. 13, in one embodiment, the side of the silicon interposer plate 160 away from the chipsets 140 may be thinned by grinding or chemical mechanical polishing processes, to expose the plurality of conductive connection structures 162. Therefore, the plurality of conductive connection structures 162 may penetrate through the silicon interposer plate 160 along the thickness direction of the silicon interposer plate 160, forming silicon through holes to achieve better vertical electrical connection.

In the present disclosure, each wafer may be cut to form the plurality of heterogeneous chips. The plurality of target heterogeneous chips may be selected from the plurality of heterogeneous chips to form the chipsets, and the chipsets may be bonded to the silicon interposer plate. Warping or cracking of the silicon interposer plate when thinning the silicon interposer plate after interconnecting the chipsets to the silicon interposer plate may be avoided. By cutting the plurality of wafers to form the plurality of heterogeneous chips and selecting the plurality of target heterogeneous chips from the plurality of heterogeneous chips to reorganize to form the chipsets. The reorganized chipsets may be molded together with the silicon interposer plate at one time, thereby improving the overall integration of the chip package.

In S160, the silicon interposer plate and the chipsets after bonding may be cut to form a plurality of chip micro-modules. Each of the plurality of chip micro-modules may include one of the chipsets.

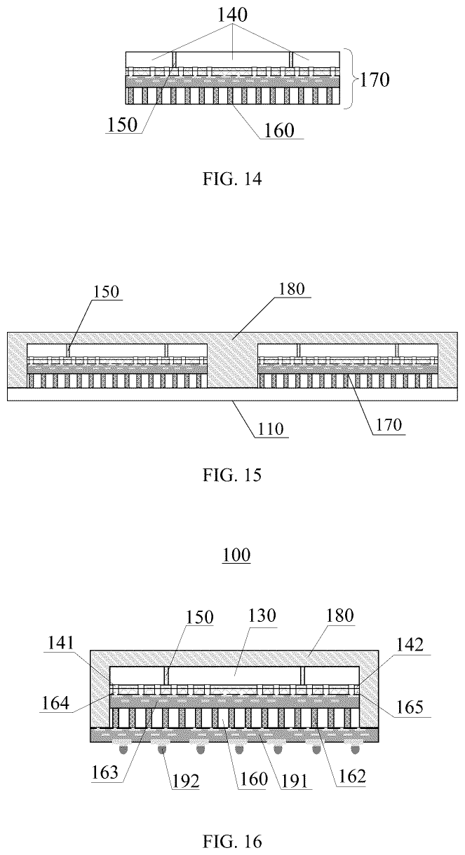

As shown in FIG. 14, in one embodiment, the silicon interposer plate 160 and the chipsets 140 after bonding may be cut to form the plurality of chip micro-modules 170. Each of the plurality of chip micro-modules 170 may include one of the chipsets 140. That is, each chip micro-module 170 may include a cut silicon interposer plate 160 and a chipsets 140 composed of two first chips 130a and one second chip 130b.

Further, as shown in FIG. 4, during the cutting process, the first plastic encapsulation layer 150 in the edge area of each chipsets 140 in each chip micro-module 170 may need to be cut off, such that the edge area of the chipsets 140 may be flush with the edge areas of the silicon interposer plate 160 after cutting. That is, in this embodiment, the first plastic encapsulation layer 150 in the edge areas of the two first chips 130a may be cut off, and the edge areas of the two first chips 130a may be flush with the edge areas of the cut silicon interposer plate 160, for subsequent packaging.

In S170, a side of the silicon interposer plate of the plurality of chip micro-modules may be fixed to the carrier, and a second plastic encapsulation layer may be formed on a side of the plurality of chip micro-modules away from the carrier.

As shown in FIG. 15, in one embodiment, the side of the silicon interposer plate 160 of the plurality of chip micro-modules 170 away from the plurality of the chipsets 140 may be fixed to the carrier 110, and then the second plastic encapsulation layer 180 may be formed on a side of the plurality of chip micro-modules 170 away from the carrier 110. The second plastic encapsulation layer 180 may wrap and protect the plurality of chip micro-modules 170.

In one embodiment, the second plastic encapsulation layer 180 may be formed using a compression molding process, a transfer molding process, a liquid sealing molding process, a vacuum lamination process or a spin coating process, which is not specifically limited in this embodiment. The second plastic encapsulation layer 180 may be made of a material including polyimide, silicone, epoxy resin, or similar materials.

In S180, the carrier may be removed and the second plastic encapsulation layer may be cut to form independent packaging structures.

As shown in FIG. 16, in one embodiment, the carrier 110 may be removed using thermal separation, laser separation, ultra-violet separation, or mechanical separation. Then, the second plastic encapsulation layer 180 may be cut to form independent packaging structures. Each independent packaging structure may include the second plastic encapsulation layer 180 and one chip micro-module 170.

In some embodiments, after cutting the second plastic encapsulation layer, the method may further include:
as shown in FIG. 16, a second redistribution layer 191 may be formed on the side of the silicon interposer plate 160 away from the chipsets 140. The structure f the second redistribution layer 191 may be consistent with the first redistribution layer 163.

As shown in FIG. 16, a plurality of solder balls 192 may be formed on the second redistribution layer 191 to form the independent packaging structure. The entire package structure may be electrically connected to the outside world through the plurality of solder balls 192.

In the present disclosure, each wafer may be cut to obtain the plurality of heterogeneous chips. The plurality of target heterogeneous chips may be selected from the plurality of heterogeneous chips to form the chipsets, and the chipsets may be bonded to the silicon interposer plate. Warping or cracking of the silicon interposer plate when thinning the silicon interposer plate after interconnecting the chipsets to the silicon interposer plate may be avoided. Multiple target heterogeneous chips are selected from the heterogeneous chips and reorganized to form a chipsets. The reorganized multiple chipsets can be molded together with the silicon interposer at one time, improving the overall integration of the chip package. By cutting the plurality of wafers to form the plurality of heterogeneous chips and selecting the plurality of target heterogeneous chips from the plurality of heterogeneous chips to reorganize to form the chipsets. The reorganized chipsets may be molded together with the silicon interposer plate at one time, thereby improving the overall integration of the chip package.

The present disclosure also provides a chip packaging structure. As shown in FIG. 16, in one embodiment, the chip packaging structure 100 may include a plurality of chips 130, a silicon interposer plate 160, a bonding structure (not shown in the figure), a first plastic encapsulation layer 150 and a second plastic encapsulation layer 180.

In one embodiment, the plurality of chips 130 may be a plurality of heterogeneous chips 130, and the plurality of heterogeneous chips 130 may be bonded to the silicon interposer plate 160 through the bonding structure.

The first plastic encapsulation layer 150 may wrap the plurality of heterogeneous chips 130.

The second plastic packaging layer 180 may wrap the silicon interposer 160, the plurality of heterogeneous chips 130 and the first plastic packaging layer 150.

In one embodiment, as shown in16, a plurality of conductive connection structures 162 distributed at intervals may be provided on the silicon interposer 160.

A first redistribution layer 163 may be disposed on one side of the plurality of conductive connection structures 162 facing the plurality of heterogeneous chips 130. The first redistribution layer 163 may be electrically connected to the plurality of conductive connection structures 162. In one embodiment, the plurality of conductive connection structures 162 may be silicon through holes. The silicon through holes may be used to realize vertical electrical interconnection and reduce the packaging height.

In one embodiment, the first redistribution layer 163 may include a dielectric layer (not shown in the figure) and a metal layer (not shown in the figure) disposed on the dielectric layer. The dielectric layer may be made of a material including polyimide (PI), polybenzoxazole (PBO), etc., and the coating method may be usually chip spin coating, which is not specifically limited in this embodiment. The metal layer may be made of a material including titanium, copper, or other metal materials, which is not specifically limited in this embodiment.

In one embodiment, as shown in FIG. 16, the bonding structure may include a plurality of first metal pads 141 and a first passivation layer 142 disposed on the side of the plurality of heterogeneous chips 130 and the first plastic encapsulation layer 150 facing the silicon interposer plate 160, and a plurality of second metal pads 164 and a second passivation layer 165 on one side of the first redistribution layer 163 facing the plurality of heterogeneous chips 130.

The plurality of second metal pads 164 may be bonded to the plurality of first metal pads 141 correspondingly, and the second passivation layer 165 may be bonded to the first passivation layer 142. That is, the bonding structure may be a hybrid bonding structure.

The plurality of first metal pads 141 and the plurality of second metal pads 164 may be made of a material including metal copper or other metal materials, and there is no specific limitation in this embodiment. The positions of the plurality of first metal pads 141 may correspond to the positions of the plurality of second metal pads 164.

The first passivation layer 142 or the second passivation layer 165may be a silicon dioxide layer or a silicon nitride layer, or may be made of other materials that can play a passivation role, which is not specifically limited in this embodiment.

In the above embodiment, the silicon interposer plate 160 and the plurality of heterogeneous chips 130 may be bonded and connected through the hybrid bonding structure to achieve vertical interconnection. Through the hybrid bonding structure, the packaging height may be reduced to the greatest extent and ultra-thin packaging may be achieved.

In one embodiment shown in FIG. 16, the packaging structure 100 may further include a second redistribution layer 191 and a plurality of solder balls 192. The second redistribution layer 191 may be disposed on a side of the silicon interposer plate 160 away from the plurality of heterogeneous chips 130, and the plurality of solder balls 192 may be disposed on the second redistribution layer 191. The package structure 100 may be electrically connected to the outside world through the plurality of solder balls 192.

In the present disclosure, the plurality of heterogeneous chips may be molded with the silicon interposer plate at one time through the bonding structure, thereby improving the overall integration of the chip package. The first plastic encapsulation layer may wrap the plurality of heterogeneous chips and then may be bonded and connected with the silicon interposer plate, to avoid warping or cracking of the silicon interposer plate during the bonding and connection process.

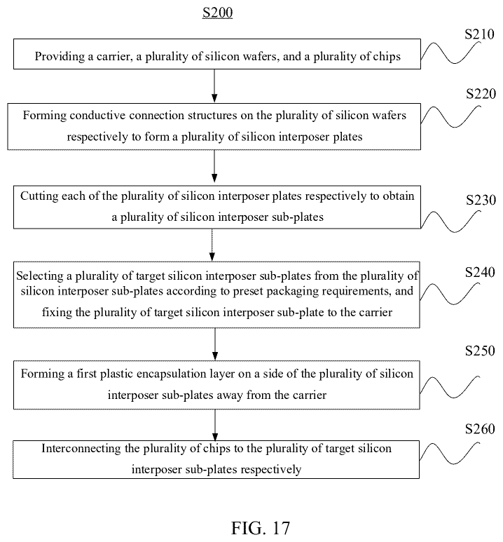

The present disclosure also provides another fan-out chip packaging method. In one embodiment, shown in FIG. 17, the method S200 may include S210 to S260.

In S210, a carrier, a plurality of silicon wafers, and a plurality of chips may be provided.

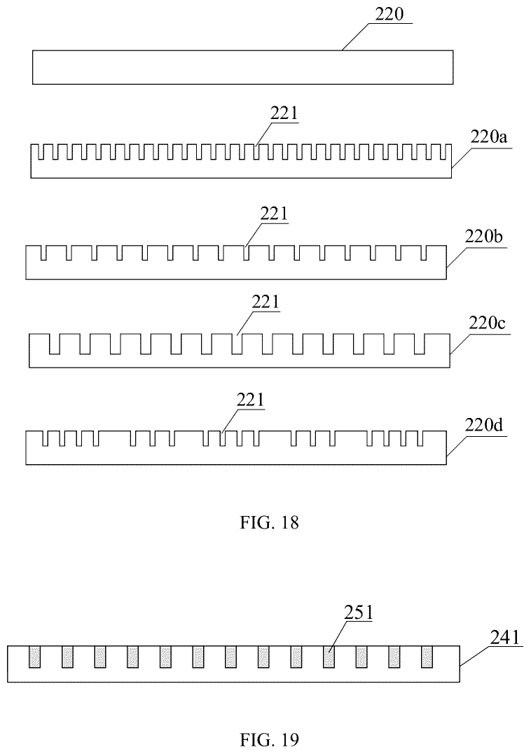

In one embodiment, as shown in FIG. 18 to FIG. 56, the carrier 210, the plurality of silicon wafers 220, and the plurality of chips 230 may be provided. The carrier 210 may be made of a material including glass, silicon wafer or metal, which is not specifically limited in this embodiment. The number of the plurality of silicon wafers 220 and the number of the plurality of chips 230 are not specifically limited in this embodiment, and can be selected according to actual needs.

In various embodiments, the plurality of chips 230 may be chips of the same type or heterogeneous chips. In this embodiment, the plurality of chips 230 may be heterogeneous chips.

In S220, conductive connection structures may be formed on the plurality of silicon wafers respectively, to form a plurality of silicon interposer plates. The conductive connection structure on at least one of the plurality of silicon interposer plates may be different from the conductive connection structures on others of the plurality of silicon interposer plates.

In one embodiment, as shown in FIG. 18 to FIG. 27, the conductive connection structures (not shown in figures) may be formed on the plurality of silicon wafers 220 respectively, to form the plurality of silicon interposer plates. The conductive connection structure on at least one of the plurality of silicon interposer plates may be different from the conductive connection structures on others of the plurality of silicon interposer plates. That is, different conductive connection structures may be formed on different silicon wafers 120 respectively.

In the present embodiment, the conductive connection structures may be formed on the plurality of silicon wafers respectively, to form the plurality of silicon interposer plates. The manufacturing process may be simple, the process difficulty may be small, and the implementation may be relatively easy. The conductive connection structure on at least one of the plurality of silicon interposer plates may be different from the conductive connection structures on others of the plurality of silicon interposer plates. Highly integrated packaging may be achieved and packaging requirements for packaging the silicon interposer plates with the plurality of heterogeneous chips may be satisfied.

In one embodiment as shown in FIG. 18 and FIG. 19, S220 may include:
S2101: forming a plurality of blind holes on at least one of the plurality of silicon wafers, where the plurality of blind holes on at least one of the plurality of silicon wafers may be different from the plurality of blind holes on others of the plurality of silicon wafers; and
S2102: filling the plurality of sets of blind holes with conductive materials to form the conductive connection structures.

In one embodiment, as shown in FIG. 18, through photolithography and etching processes, the plurality of blind holes 221 may be formed on a front surface of the at least one silicon wafer 220. Then, an insulating layer, a diffusion barrier layer, and a seed layer (not shown in the figure) may be deposited on sidewalls of each blind hole 221. The plurality of blind holes 221 formed on the front surface of at least one silicon wafer 220 may be different from the plurality of blind holes 221 formed on the front surfaces of the remaining silicon wafers 220.

That is, the plurality of blind holes 221 with different height, depth, width, or space may be formed on different silicon wafers 220. For example, in one embodiment, the plurality of blind holes 221 on each silicon wafer 220 may have different ratio between height, depth and width, or the distance between the plurality of blind holes 221 may be different. For example, in one embodiment shown in FIG. 17, the plurality of blind holes 221 equally spaced with relatively small space may be formed on a first silicon wafer 220a, the plurality of blind holes 221 equally spaced with a relatively large space may be formed on a second silicon wafer 220b, the plurality of blind holes 221 equally spaced with a relatively large space, depth, height, and width, may be formed on a third silicon wafer 220c, and the plurality of blind holes 221 with different and large space, and small depth, height and width may be formed on a fourth silicon wafer 220d. The specifications of the plurality of blind holes 221 on each silicon wafer 220 may also have other configurations, which is not limited in the present disclosure.

In the present disclosure, the plurality of blind holes formed on the front surface of at least one silicon wafer may be different from the plurality of blind holes formed on the front surfaces of the remaining silicon wafers. Therefore, the conductive connection structures with different integration levels may be formed, improving the overall integration level of the packaging.

As shown in FIG. 19, in one embodiment, the conductive materials may be filled into the plurality of blind holes 221 through processes including electroplating, and then the surfaces of the plurality of blind holes 221 may be planarized through a chemical mechanical polishing process to form the conductive connection structures, that is, first conductive connection structures 251.

As shown in FIG. 19, in the present embodiment, the first conductive connection structures 251 may be formed on the plurality of silicon wafers 220 to form the first silicon interposer plates 241. That is, the first silicon interposer plates 241 may be provided with the plurality of blind holes 221 filled with conductive materials.

In another embodiment shown in FIG. 18 to FIG. 21, S220 may include:
S2201: forming a plurality of blind holes 221 on the front surface of at least one silicon wafer 220, where the plurality of blind holes 221 formed on the front surface of at least one silicon wafer 220 may be different from the plurality of blind holes 221 formed on the front surfaces of the remaining silicon wafers 220, as shown in FIG. 18, similar to S2101;
S2202: filling the plurality of blind holes 221 with conductive materials through a process including electroplating, as shown in FIG. 19, similar to S2102; and
S2203: thinning back surfaces of the plurality of silicon wafers until exposing the plurality of blind holes, to form the conductive connection structures.

For S2201 and S2202, the references may be made to the previous description about S2101 and S2102.

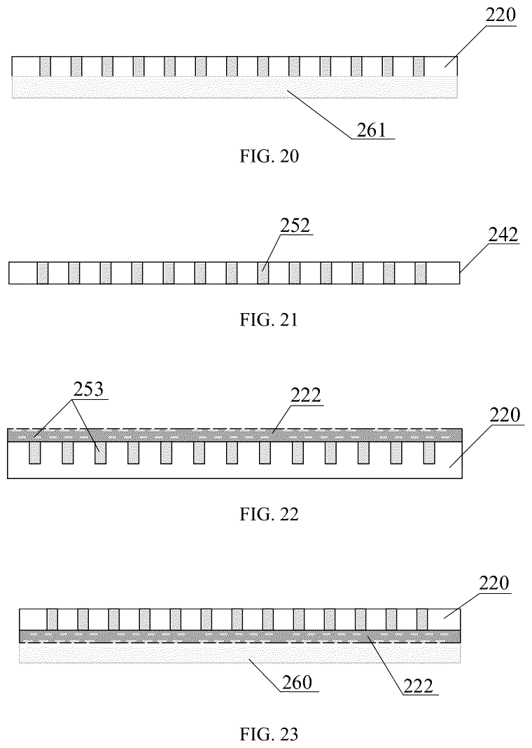

In one embodiment, after the plurality of blind holes 221 is filled with conductive materials through a process including electroplating, as shown in FIG. 20, the front surfaces of the plurality of silicon wafers 220 may be fixed on a temporary carrier 260, and then the back surfaces of the plurality of silicon wafers 220 may be ground and thinned until the plurality of blind holes 221 is exposed. As shown in FIG. 21, the temporary carrier 260 may be removed to form the conductive connection structures. That is, in this embodiment, after the plurality of blind holes 221 is filled with conductive material, the front surfaces of the plurality of silicon wafers 220 may be fixed on the temporary carrier 260, and a grinding process may be used to grind the back surfaces of the plurality of silicon wafers 220 to remove excess silicon materials, and then the temporary carrier 260 may be removed to form the second conductive connection structures 252. The second conductive connection structures 252 may be silicon through holes filled with conductive materials.

As shown in FIG. 21, in the present embodiment, the second conductive connection structures 252 may be formed on the plurality of silicon wafers 220 to form the second silicon interposer plates 242. That is, the second silicon interposer plates 242 may be provided with silicon through holes for leading out the functions of the second silicon interposer plates 242.

In another embodiment shown in FIG. 18 to FIG. 24, S220 may include:
S2301: forming a plurality of blind holes 221 on the front surface of at least one silicon wafer 220, where the plurality of blind holes 221 formed on the front surface of at least one silicon wafer 220 may be different from the plurality of blind holes 221 formed on the front surfaces of the remaining silicon wafers 220, as shown in FIG. 2;
S2302: filling the plurality of blind holes 221 with conductive materials, as shown in FIG. 3;
S2303: forming a redistribution layer on the plurality of blind holes 221; and
S2304: thinning back surfaces of the plurality of silicon wafers until exposing the plurality of blind holes, to form the conductive connection structures.

For S2301 and S2302, the references may be made to the previous description about S2101 and S2102.

In one embodiment, as shown in FIG. 22, the redistribution layer may be formed on the plurality of blind holes 221 after being filled with conductive materials. That is, the redistribution layer may be formed on the front surfaces of the plurality of silicon wafters 220, ad may be electrically connected to the plurality of blind holes 221 filled with conductive materials.

In one embodiment, the redistribution layer 222 may include a dielectric layer (not shown in the figure) and a metal layer (not shown in the figure) disposed on the dielectric layer. The dielectric layer may be formed on the surfaces of the plurality of silicon wafers 220 provided with the plurality of blind holes 221 by coating. The dielectric layer may be patterned using a photolithography process, to form a plurality of openings on the dielectric layer. And then, the metal layer may be formed on the patterned dielectric layer by a process including sputtering or electroplating.

The dielectric layer may be made of a material including polyimide (PI), polybenzoxazole (PBO), etc., and the coating method may include heterogeneous chip spin coating, which is not specifically limited in the present disclosure. The metal layer may be made of a material including titanium, copper, or other metal materials, which are not specifically limited in the present disclosure.

In another embodiment, the redistribution layer 222 may be formed by: forming a photoresist layer on the surfaces of the plurality of silicon wafers 220 provided with the plurality of blind holes 221, patterning the photoresist layer to form a plurality of openings, and forming a thick metal layer on the plurality of openings by sputtering, to form the redistribution layer 222.

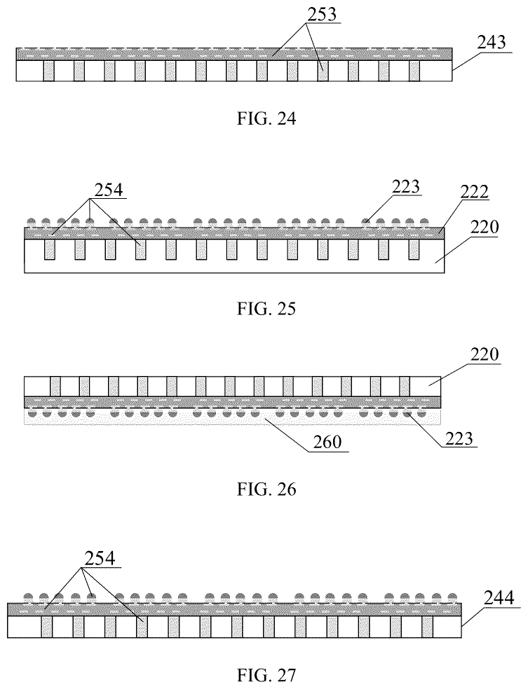

In one embodiment shown in FIG. 23, the redistribution layer 222 may be fixed on a temporary carrier board 260, and then the back surfaces of the plurality of silicon wafers 220 may be ground and polished to remove excess silicon materials the plurality of blind holes 221 are exposed. As shown in FIG. 24, the temporary carrier board 260 may be removed, to form the third conductive connection structures 253. That is, the third conductive connection structures 253 may include silicon through holes and the redistribution layer 222 disposed on the silicon through silicon holes.

As shown in FIG. 24, in the present embodiment, the third conductive connection structures 253 may be formed on the plurality of silicon wafers 220 to form the third silicon interposer plates 243. That is, the third silicon interposer plate 243 may be provided with silicon through holes and the redistribution layer 222 on the silicon through holes. The redistribution layer 222 may reorganize the signals led out by the silicon through holes and then lead out the signals of the third silicon interposer plate 243 as a whole.

In another embodiment shown in FIG. 18 to FIG. 26, S220 may include:
S2401: forming a plurality of blind holes 221 on the front surface of at least one silicon wafer 220, where the plurality of blind holes 221 formed on the front surface of at least one silicon wafer 220 may be different from the plurality of blind holes 221 formed on the front surfaces of the remaining silicon wafers 220, as shown in FIG. 2;
S2402: filling the plurality of blind holes 221 with conductive materials, as shown in FIG. 3;
S2403: forming a redistribution layer 222 on the plurality of blind holes 221; and
S2404: forming soldering balls on the redistribution layer 222; and
S405: thinning back surfaces of the plurality of silicon wafers until exposing the plurality of blind holes, to form the conductive connection structures.

For S2401 and S2402, the references may be made to the previous description about S2101 and S2102. S2403 may be similar to S2303.

In one embodiment, as shown in FIG. 25, soldering ball planting may be performed on the redistribution layer 222 to form the plurality of soldering balls 223.

In one embodiment as shown in FIG. 26, the plurality of soldering balls 223 may be fixed on a temporary carrier board 260, and then the back surfaces of the plurality of silicon wafers 220 may be ground and polished to remove excess silicon materials the plurality of blind holes 221 are exposed. As shown in FIG. 11, the temporary carrier board 260 may be removed, to form the fourth conductive connection structures 254. That is, the fourth conductive connection structures 254 may include silicon through holes, the redistribution layer 222 disposed on the silicon through silicon holes, and the plurality of soldering balls 223 on the redistribution layer 222.

As shown in FIG. 27, in the present embodiment, the fourth conductive connection structures 254 may be formed on the plurality of silicon wafers 220 to form the fourth silicon interposer plates 244. That is, the fourth silicon interposer plates 244 may be provided with silicon through holes, the redistribution layer 222 on the silicon through holes, and the plurality of soldering balls 223 on the redistribution layer 222. The redistribution layer 222 and the plurality of soldering balls 223 on the redistribution layer 222 may reorganize the signals led out by the silicon through holes and then lead out the signals of the fourth silicon interposer plate 244 as a whole.

In other embodiments, other types of silicon interposer plates may be provided, according to actual needs. The types of silicon interposer plates are not limited in the present disclosure.

In S230, each of the plurality of silicon interposer plates may be cut respectively to obtain a plurality of silicon interposer sub-plates.

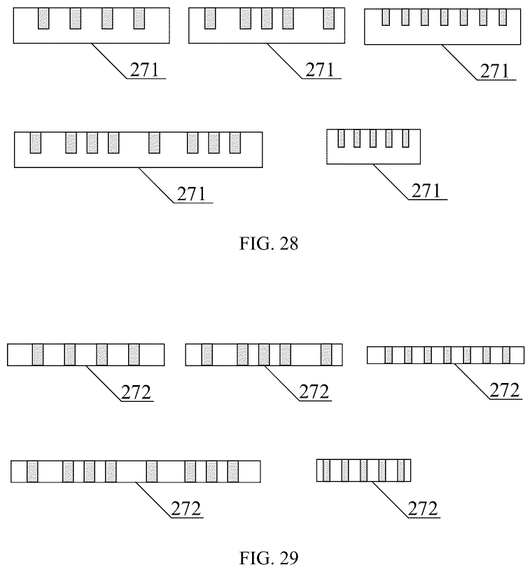

In one embodiment shown in FIG. 28 to FIG. 31, each of the plurality of silicon interposer plates may be cut respectively to obtain the plurality of silicon interposer sub-plates. As shown in FIG. 27, in one embodiment, the first silicon interposer plates 241 may be cut and separated, to obtain a plurality of first silicon interposer sub-plates 271. Different silicon interposer sub-plates formed by cutting different silicon interposer plates may be different. For example, the first silicon interposer plates 241 with different structures may be cut and separated to form the plurality of first silicon interposer sub-plates 271, and the conductive connection structures on each of the plurality of first silicon interposer sub-plates 271 may have different density, width, or depth. Therefore, according to different packaging requirements, suitable first silicon interposer sub-plates 271 may be adopted for packaging based on the needs, improving the packaging integration levels.

As shown in FIG. 29, in one embodiment, the second silicon interposer plates 242 may be cut and separated, to obtain a plurality of second silicon interposer sub-plates 272. Different silicon interposer sub-plates formed by cutting different silicon interposer plates may be different. For example, the second silicon interposer plates 242 with different structures may be cut and separated to form the plurality of second silicon interposer sub-plates 272, and the conductive connection structures on each of the plurality of second silicon interposer sub-plates 272 may have different density, width, or depth. Therefore, according to different packaging requirements, suitable second silicon interposer sub-plates 272 may be adopted for packaging based on the needs, improving the packaging integration levels.

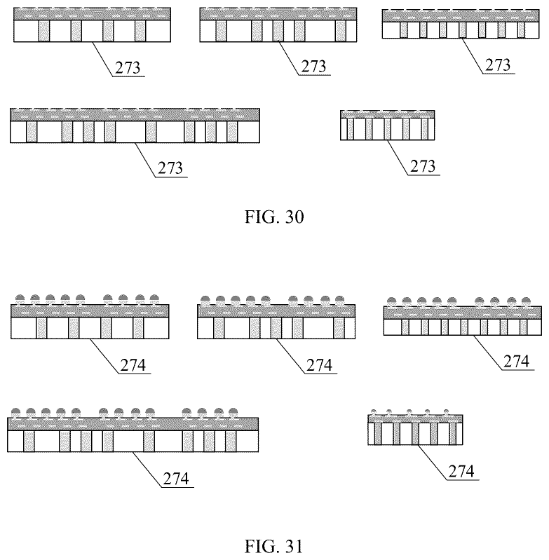

As shown in FIG. 30, in one embodiment, the third silicon interposer plates 243 may be cut and separated, to obtain a plurality of third silicon interposer sub-plates 273. Different silicon interposer sub-plates formed by cutting different silicon interposer plates may be different. For example, the third silicon interposer plates 243 with different structures may be cut and separated to form the plurality of third silicon interposer sub-plates 273, and the conductive connection structures on each of the plurality of third silicon interposer sub-plates 273 may have different density, width, or depth. Therefore, according to different packaging requirements, suitable third silicon interposer sub-plates 123 may be adopted for packaging based on the needs, improving the packaging integration levels.

As shown in FIG. 31, in one embodiment, the fourth silicon interposer plates 244 may be cut and separated, to obtain a plurality of fourth silicon interposer sub-plates 274. Different silicon interposer sub-plates formed by cutting different silicon interposer plates may be different. For example, the fourth silicon interposer plates 244 with different structures may be cut and separated to form the plurality of fourth silicon interposer sub-plates 274, and the conductive connection structures on each of the plurality of fourth silicon interposer sub-plates 274 may have different density, width, or depth. Therefore, according to different packaging requirements, suitable fourth silicon interposer sub-plates 274 may be adopted for packaging based on the needs, improving the packaging integration levels.

In one embodiment, by cutting different silicon interposer plates obtained in the above steps, the plurality of silicon interposer sub-plates of various specifications may be obtained. The conductive connection structures, depth, width, or density of holes in each type of silicon interposer block may be different. Of course, the fourth types of silicon interposer sub-plates are used as examples to illustrate the present disclosure only and do not limit the scopes of the present disclosure. There may be other types of silicon interposer sub-plates.

The same type of silicon interposer sub-plates may also have conductive connection structures with different integration levels. For example, for first silicon interposer sub-plate sub-plates271, the integration level of the conductive connection structures of each first silicon interposer sub-plate 271 may be different. For example, the density, width, depth, etc. of the conductive connection structures may be different.

In S240, a plurality of target silicon interposer sub-plates may be selected from the plurality of silicon interposer sub-plates according to the preset packaging requirements, and the plurality of target silicon interposer sub-plates may be fixed on the carrier.

According to the preset packaging requirements, the plurality of target silicon interposer sub-plates may be selected from the plurality of silicon interposer sub-plates, and the front surfaces of the plurality of target silicon interposer sub-plates may be fixed on the carrier board 210. That is, according to different packaging requirements, the plurality of target silicon interposer sub-plates may be selected from the plurality of silicon interposer sub-plates. Then, the plurality of target silicon interposer sub-plates may be combined according to the packaging requirements, and then the front surfaces of the plurality of target silicon interposer sub-plates may be fixed on the carrier 210.

In one embodiment, selecting the plurality of target silicon interposer sub-plates from the plurality of silicon interposer sub-plates and fixing the plurality of target silicon interposer sub-plates to the carrier board may include:
at least one of the plurality of target silicon interposer sub-plates have the conductive connection structure 250 different from the conductive connection structures 250 of other target silicon interposer sub-plates of the plurality of target silicon interposer sub-plates.

In the present embodiments, the conductive connection structure of at least one of the plurality of target silicon interposer sub-plates may be different from the conductive connection structures of other target silicon interposer sub-plates of the plurality of target silicon interposer sub-plates. Different target silicon interposer sub-plates may be selected for packaging according to the packaging requirements of different chips, to improve the packaging integration level when packaging the silicon interposer sub-plates with the plurality of chips and meet the packaging requirements of different chips.

The plurality of target silicon interposer sub-plates may include the same type of silicon interposer sub-plates or different types of silicon interposer sub-plates. That is, in this embodiment, the plurality of target silicon interposer sub-plates may be selected from one or more of the first silicon interposer sub-plates 271, the second silicon interposer sub-plates 272, the third silicon interposer sub-plates 273, or the fourth silicon interposer sub-plates 274 to be combined and then the front surfaces may be fixed on the carrier board 210. This present disclosure does not specifically limit the selection of the target silicon interposer sub-plates, and the selection may be made according to actual needs.

In one embodiment, the plurality of target silicon interposer sub-plates may be the same type of silicon interposer sub-plates, and the conductive connection structure 250 of at least one of the plurality of target silicon interposer sub-plates may be different from the conductive connection structures 250 of other target silicon interposer sub-plates of the plurality of target silicon interposer sub-plates. For example, the plurality of target silicon interposer sub-plates may be the first silicon interposer sub-plates 271, but the first conductive connection structures 251 in each first silicon interposer sub-plates 271 may be also different, such as the spacing, depth or width of the first conductive connection structures 251 may be different.

In the present disclosure, according to the preset packaging requirements, the plurality of target silicon interposer sub-plates may be selected from the plurality of silicon interposer sub-plates, and the plurality of target silicon interposer sub-plates may be fixed to the carrier board. Therefore, warping or cracking of the silicon interposers may be avoided when the plurality of chips is bonded to the plurality of target silicon interposer sub-plates. The conductive connection structures of at least one of the plurality of target silicon interposer sub-plates may be different from the conductive connection structures of others of the plurality of target silicon interposer sub-plates. The reorganized silicon interposer sub-plates may be formed with the plurality of chips at one time, thereby improving the integration level of chip packaging.

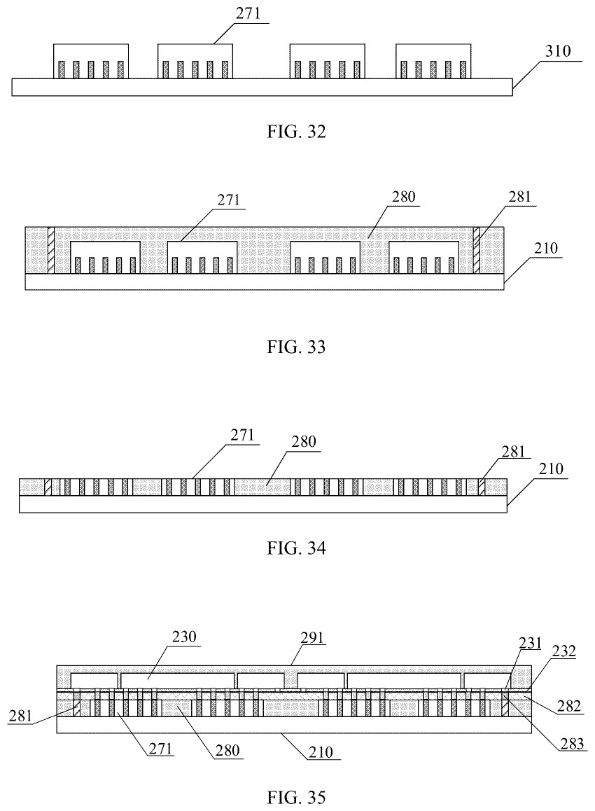

In one embodiment shown in FIG. 32, In one embodiment, selecting the plurality of target silicon interposer sub-plates from the plurality of silicon interposer sub-plates and fixing the front surfaces of the plurality of target silicon interposer sub-plates to the carrier board may include:
fixing the front surfaces or the back surfaces of the plurality of target silicon interposer sub-plates to the carrier board 210; or
fixing the front surface of at least one of the plurality of target silicon interposer sub-plates to the carrier board 210 and fixing the back surfaces of remaining of the plurality of target silicon interposer sub-plates to the carrier board 210.

The fixing direction of the target silicon interposer sub-plates is not limited in the present disclosure, and may be selected according to actual needs.

In one embodiment, as shown in FIG. 32, the plurality of first silicon interposer sub-plates 271 may be selected as target silicon interposer sub-plates, and the front surfaces of the plurality of first silicon interposer sub-plates 271 may be fixed on the carrier board 210. As shown in FIG. 21, in another embodiment, the back surfaces of the plurality of first silicon interposer sub-plates 271 may be fixed on the carrier board 210. The fixing direction of the plurality of first silicon interposer sub-plates 171 may be selected according to actual needs, and is not specifically limited in this embodiment.

Similarly, in another embodiment, the plurality of second silicon interposer sub-plates 272 may also be selected as target silicon interposer sub-plates, and then the front or back surfaces of the plurality of second silicon interposer sub-plates 172 may be fixed to the carrier board 210.

In another embodiment, as shown in FIG. 41, the plurality of third silicon interposer sub-plates 273 may be selected as target silicon interposer sub-plates, and the back surfaces of the plurality of third silicon interposer sub-plates 273 may be fixed on the carrier board 210. Of course, in another embodiment, the front surfaces of the plurality of third silicon interposer sub-plates 273 may also be fixed on the carrier board 210. The fixing directions of the plurality of third silicon interposer sub-plates 273 may be selected according to actual needs, and are not specifically limited in this embodiment.

In another embodiment, as shown in FIG. 47, a combination of a plurality of second silicon interposer sub-plates 272 and a plurality of third silicon interposer sub-plates 273 may be selected as the target silicon interposer sub-plate. The front surfaces of the plurality of second silicon interposer sub-plates 272 and the front surfaces of the plurality of third silicon interposer sub-plates 273 may be fixed on the carrier board 210. Of course, in another embodiment, the back surfaces of the second silicon interposer sub-plate 272 and the back surfaces of the plurality of third silicon interposer sub-plates 273 may also be fixed on the carrier board 210. The front and back surfaces of the plurality of second silicon interposer sub-plates 272 may be fixed on the carrier 210 in the same way, and only the fixing directions of the plurality of third silicon interposer sub-plates 273 needs to be selected. The fixing directions of the plurality of third silicon interposer sub-plate 273 can be selected according to actual needs, and are not specifically limited in this embodiment.

In another embodiment, as shown in FIG. 52, a plurality of fourth silicon interposer sub-plates 274 may be selected as target silicon interposer sub-plates, and the front surfaces of the plurality of fourth silicon interposer sub-plates 274 may be fixed on the carrier board 210. Of course, in another embodiment, the back surfaces of the plurality of fourth silicon interposer sub-plates 274 may be also be fixed on the carrier board 210. The fixing directions of the plurality of fourth silicon interposer sub-plates 174 may be selected according to actual needs, and are not specifically limited in this embodiment.

It should be noted that in other embodiments, those skilled in the art may also select other different types of silicon interposer sub-plates as needed and combine them as target silicon interposer sub-plates, and then fix the target silicon interposer sub-plates on the carrier board 210. For example, a combination of the second silicon interposer sub-plates 272 and the fourth silicon interposer sub-plates 274 may be selected as the target silicon interposer sub-plates, etc. The selection may be made according to actual needs, and is not specifically limited in this embodiment.

In the present disclosure, according to the preset packaging requirements, the plurality of target silicon interposer sub-plates may be selected from the plurality of silicon interposer sub-plates, and the plurality of target silicon interposer sub-plates may be fixed to the carrier board. Therefore, warping or cracking of the silicon interposers may be avoided when the plurality of chips is bonded to the plurality of target silicon interposer sub-plates. The conductive connection structures of at least one of the plurality of target silicon interposer sub-plates may be different from the conductive connection structures of others of the plurality of target silicon interposer sub-plates. The reorganized silicon interposer sub-plates may be formed with the plurality of chips at one time, thereby improving the integration level of chip packaging.

In S250, a first plastic encapsulation layer may be formed on the back surfaces of the plurality of target silicon interposer sub-plates.

As shown in FIG. 33, FIG. 41, FIG. 47, and FIG. 52, after fixing the plurality of target silicon interposer sub-plates on the carrier 210, the first plastic encapsulation layer 280 may be formed on a side of the plurality of target silicon interposer sub-plates away from the carrier 210. The first plastic encapsulation layer 280 may wrap the plurality of target silicon interposer sub-plates, to protect the plurality of target silicon interposer sub-plates. The first plastic encapsulation layer may be formed by a film vacuum lamination or an existing plastic encapsulation.

In one embodiment, as shown in FIG. 33, FIG. 41, FIG. 47, and FIG. 52, after forming the first plastic encapsulation layer 280 on the side of the plurality of target silicon interposer sub-plates away from the carrier, the method may further include:

forming a plurality of first through holes in the first plastic encapsulation layer 280 along its thickness direction, and filling the plurality of first through holes with conductive materials to form a plurality of first interconnection conductive pillars 281.

In one embodiment, before interconnecting the plurality of chips to the plurality of target silicon interposer sub-plates, the method may further include:

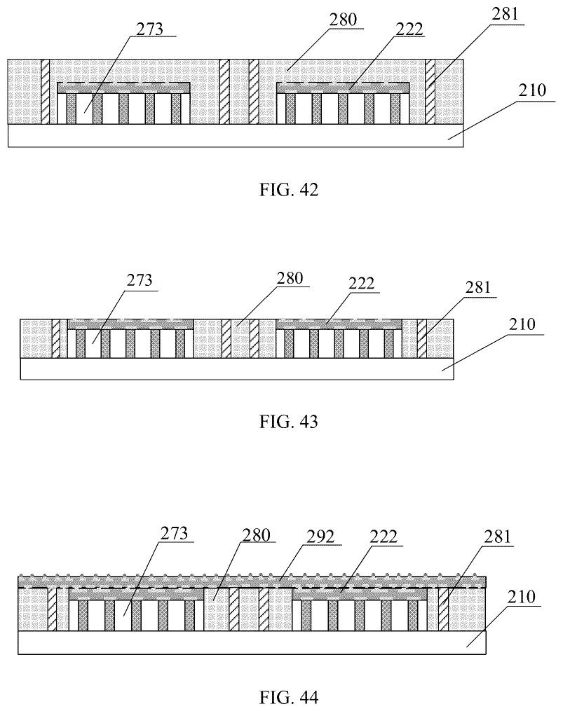

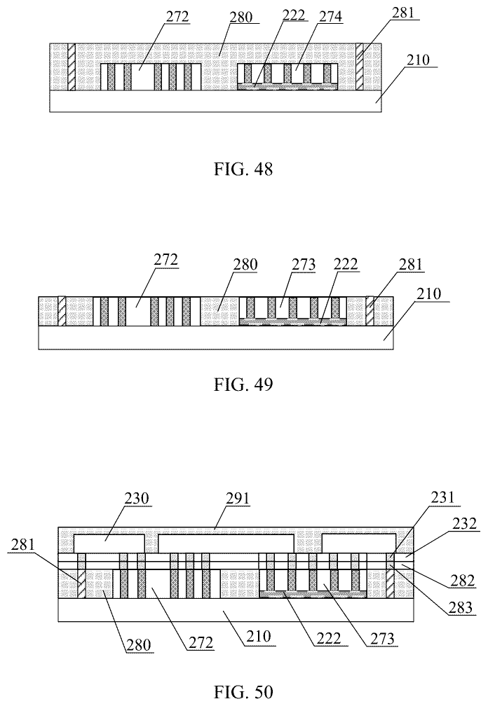

As shown in FIG. 34, FIG. 42, FIG. 48, and FIG. 53, thinning a side of the first plastic encapsulation layer 280 away from the carrier 210 to expose the conductive connections structures of the plurality of target silicon interposer sub-plates and the plurality of first interconnection conductive pillars 281.

In the present embodiment, the side of the first plastic encapsulation layer 280 away from the carrier 210 to expose the conductive connections structures and the plurality of first interconnection conductive pillars 281, to prepare interconnecting the plurality of chips to the plurality of target silicon interposer sub-plates.

In S260, the plurality of chips may be interconnected to the plurality of target silicon interposer sub-plates.

In one embodiment, interconnecting the plurality of chips 230 to the plurality of target silicon interposer sub-plates may include:
forming a second plastic encapsulation layer 291 on a side of the plurality of chips 230 away from the plurality of target silicon interposer sub-plates; and
interconnecting a side of the second plastic encapsulation layer 291 and the plurality of chips 230 facing the plurality of target silicon interposer sub-plates to the front surfaces or the back surfaces plurality of target silicon interposer sub-plates through the bonding structure.

The plurality of chips 230 may be interconnected to the front or back surfaces of the plurality of target silicon interposer sub-plates through a hybrid bonding process, a thermocompression bonding process or a flip-chip process. In this embodiment, the plurality of chips 230 may include heterogeneous chips. According to the type of the plurality of chips 230 and the type of the plurality of target silicon interposer sub-plates, an appropriate process may be selected to interconnect the plurality of chips to the plurality of target silicon interposer sub-plates. The interconnection process is not specifically limited in this embodiment and can be selected according to actual needs.

As shown in FIG. 32 to FIG. 36, in one embodiment, a plurality of first silicon interposer sub-plates 271 may be selected as the plurality of target silicon interposer sub-plates, and the hybrid bonding process may be used to interconnect the plurality of chips 230 to the back surfaces of the plurality of target silicon interposer sub-plates.

As shown in FIG. 32, the plurality of first silicon interposer sub-plates 271 may be selected as the plurality of target silicon interposer sub-plates, and the front surfaces of the plurality of first silicon interposer sub-plates 271 may be fixed to a carrier 210.

As shown in FIG. 33, the first plastic encapsulation layer 280 may be formed on the back surfaces of the plurality of first silicon interposer sub-plates 271. A plurality of first through holes may be formed in the first plastic encapsulation layer 280 along the thickness direction of the first plastic encapsulation layer 280, and the plurality of first through holes may be filled with conductive materials to form the plurality of first interconnection conductive pillars 281.

As shown in FIG. 34, a side of the first plastic encapsulation layer 280 may be polished to expose the first conductive connection structures and the plurality of first interconnection conductive pillars 281 of the plurality of first silicon interposer sub-plates 271.

As shown in FIG. 35, the plurality of wafers may be cut to form the plurality of different chips. In one embodiment, the plurality of heterogeneous chips 230 may be obtained.

The plurality of chips 230 may be plastically encapsulated to form the second plastic encapsulation layer 291, and then a side of the second plastic encapsulation layer 291 facing the plurality of target silicon interposer sub-plates may be polished to expose the plurality of chips.

As shown in FIG. 35, in one embodiment, the first metal pads 231 and the first passivation layer 232 may be sequentially formed on the side of the plurality of chips 130 and the second plastic encapsulation layer 191 facing the plurality of target silicon interposer sub-plates. In another embodiment, the first passivation layer 232 may be formed first, and then may be patterned through a photolithograph and etching process. The first metal pads 231 may be formed on the patterned first passivation layer 232.

In one embodiment, the first passivation layer 232 may be made of a material including a silicon dioxide passivation layer, a silicon nitride layer, or other materials that could play a passivation role, which is not specifically limited in this embodiment. The first metal pad 231 may be made of a material including metal copper or other metal materials, which is not specifically limited in this embodiment.

As shown in FIG. 35, a second passivation layer 282 and second metal pads 283 may be sequentially formed on a side of the plurality of first silicon interposer sub-plates 271 facing the plurality of chips 230. That is, the second passivation layer 282 and the second metal pads 283 may be sequentially formed on the thinned back surfaces of the plurality of first silicon interposer sub-plates 271.

In one embodiment, the second passivation layer 282 may be made of a silicon dioxide passivation layer or a silicon nitride layer, or other materials that could play a passivation role, which is not specifically limited in this embodiment. The second metal pads 283 may be made of a material including metal copper or other metal materials, which is not specifically limited in this embodiment.

As shown in FIG. 35, the first metal pads 231 and the second metal pads 283 may be bonded and connected, and the first passivation layer 232 and the second passivation layer 282 may be bonded and connected. The first metal pad 231 may also correspond to and be electrically connected to the first interconnection conductive pillars 281. Therefore, the plurality of chips 230 are bonded to the front surfaces of the plurality of target silicon interposer sub-plates.

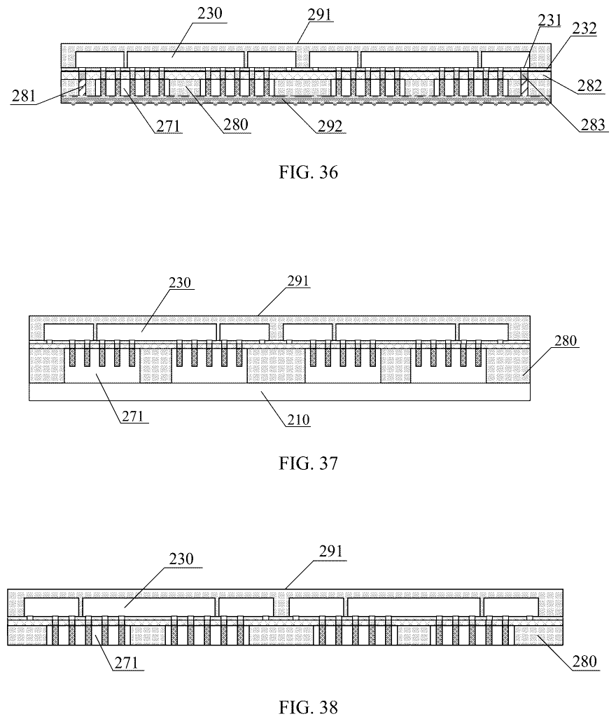

As shown in FIG. 36, after the plurality of chips 230 are interconnected to the plurality of target silicon interposer sub-plates, the carrier 210 may be removed, and then a first circuit layer 292 may be formed on a side of the plurality of first silicon interposer sub-plates 271 away from the plurality of chips 230. That is, in the present embodiment, the first circuit layer 292 may be formed on the front surfaces of the plurality of first silicon interposer sub-plates 271. The packaging structure may be connected to the outside world through the first circuit layer 192. The first circuit layer may have a structure including a redistribution layer and soldering balls, or other structures, which is not limited in the present disclosure.

In this embodiment, the first circuit layer 292 may amplify the signals from the plurality of target silicon interposer sub-plates, improve the flexibility of packaging integration, and increase the interconnection density of the packaging structure.

In another embodiment, after the first plastic encapsulation layer 280 is formed, the second passivation layer 282 and the second metal pads 283 may be formed on the front surfaces of the plurality of first silicon interposer sub-plates 271 after removing the carrier 210. The front surfaces of the interposer plurality of first silicon interposer sub-plates 271 may be bonded to the plurality of chips 230 through the second passivation layer 282 and the second metal pads 283. Then, the back surfaces of the plurality of first silicon interposer sub-plates 271 may be thinned to expose the conductive connection structures, and the first circuit layer 292 may be formed on the back surfaces of the plurality of thinned first silicon interposer sub-plates 271. The specific bonding process has been described previously and will not be repeated here.

In some other embodiments, the plurality of first silicon interposer sub-plates 271 may also be used as target silicon interposer sub-plates and the back surfaces of the plurality of first silicon interposer sub-plates 271 may be fixed on the carrier 210. The specific steps of interconnecting the plurality of chips 230 to the plurality of target silicon interposer sub-plates through a hybrid bonding process or a flip-chip process are basically the same as in the above embodiments, and will not be described again here.

As shown in FIG. 37, in one embodiment, the back surfaces of the plurality of first silicon interposer sub-plates 271 may be fixed on the carrier 210. After the plurality of chips 230 are interconnected to the plurality of target silicon interposer sub-plates through the hybrid bonding process, the carrier 210 may be removed, and the side of the first plastic encapsulation layer 280 facing the carrier 210 may be thinned to expose the first conductive connection structures 251 of the plurality of first silicon interposer sub-plates 271. That is, the back surfaces of the plurality of first silicon interposer sub-plates 271 may be thinned, and then the first circuit layer 292 may be formed on the back surfaces of the plurality of thinned first silicon interposer sub-plates 271.

In one embodiment, after interconnecting the plurality of chips to the plurality of target silicon interposer sub-plates, the method may further include: forming a plurality of first through holes in the first plastic encapsulation layer 280 along its thickness direction, and filling the plurality of first through holes with conductive materials to form a plurality of first interconnection conductive pillars 281.

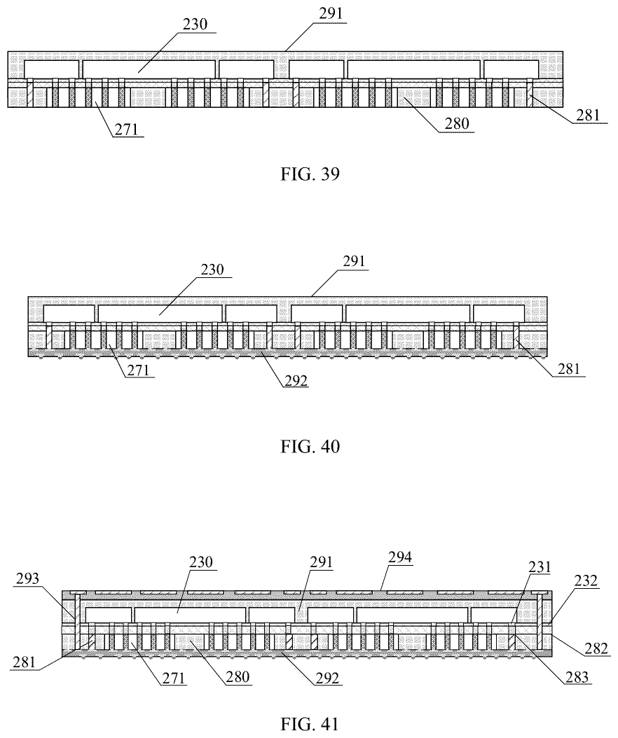

As shown in FIG. 39, after thinning the back surfaces of the plurality of first silicon interposer sub-plates 271, the plurality of first interconnection conductive pillars 281 may be formed in the first plastic encapsulation layer 280 along its thickness direction. Two ends of each of the plurality of plurality of first interconnection conductive pillars 281 may be electrically connected to the plurality of chips 230 and the first circuit layer 292 respectively.

In some embodiments shown in FIG. 33, the plurality of first interconnection conductive pillars 281 may be formed after forming the first plastic encapsulation layer 280. In the present embodiments, the plurality of first interconnection conductive pillars 281 may be formed after forming the first plastic encapsulation layer 280 on the back surfaces of the plurality of target silicon interposer sub-plates. The plurality of first interconnection conductive pillars 281 may be used to achieve the vertically electrical connection between the plurality of chips 230 and the first circuit layer 292, and the packaging height may be reduced.

As shown in FIG. 40, the first circuit layer 292 may be formed on the first conductive connection structures exposed on the back surfaces of the plurality of first silicon interposer sub-plates 271. The packaging structure may be connected to the outside world through the first circuit layer 192. The first circuit layer may have a structure including a redistribution layer and soldering balls, or other structures, which is not limited in the present disclosure. In this embodiment, the first circuit layer 292 may amplify the signals from the plurality of target silicon interposer sub-plates, improve the flexibility of packaging integration, and increase the interconnection density of the packaging structure.

In the present disclosure, the plurality of chips may be interconnected to the plurality of target silicon interposer sub-plates through the hybrid bonding structure. The production efficiency may be improved while achieving high-density interconnection. A ultra-thin packaging may be also realized.

In some other embodiments, the plurality of chips may be interconnected to the plurality of target silicon interposer sub-plates through a flip-chip process.

In one embodiment, the plastic encapsulation may be performed on the plurality of chips 230 to form the second plastic encapsulation layer 291, and a side of the second plastic encapsulation layer 291 toward the plurality of target silicon interposer sub-plates may be polished to expose the plurality of chips 230. The first metal pads 231 may be formed on a side of the plurality of chips 230 facing the plurality of target silicon interposer sub-plates.

The plurality of chips 230 may be directly mounted on the back surfaces of the plurality of first silicon interposer sub-plates through the first metal pads 231 through the flip-chip process, without forming form the second passivation layer 282 and the second metal pad 283. The first metal pads 231 may be electrically connected to the first conductive connection structures 251 and the first interconnection conductive pillars 281 exposed on the back surfaces of the plurality of first silicon interposer sub-plates 271. An underfill may be formed on the first metal pads 231 to further fix the plurality of chips 230 on the plurality of target silicon interposer sub-plates. In other embodiments, plurality of chips 230 may be directly mounted on the front surfaces of the plurality of first silicon interposer sub-plates through the first metal pads 231 through the flip-chip process, and the process may be similar.

It should be noted that in the present disclosure, in addition to the hybrid bonding process and the flip-chip process, other processes, such as a thermocompression bonding process, may be also used to interconnect the plurality of chips to the plurality of target silicon interposer sub-plates, and there is no specific limitation in this embodiment.

In some other embodiment, the plurality of target silicon interposer sub-plates may include the plurality of second silicon interposer sub-plates 272, and the specific steps of interconnecting the plurality of chips to the plurality of target silicon interposer sub-plates through a hybrid bonding process or a flip-chip process may be similar to the above embodiments and will not be described again here.

In one embodiment, as shown in FIG. 41, after forming the first circuit layer 292 on a side of the plurality of target silicon interposer sub-plates away from the plurality of chips 230, the method may further include:
forming a plurality of second through holes penetrating through the thickness direction of the first plastic encapsulation layer 280 and the second plastic encapsulation layer 291; filling conductive material in the plurality of second through holes to form a plurality of second interconnection conductive pillars 293; and forming a second circuit layer 294 on a side of the second encapsulation layer 291 away from the plurality of target silicon interposer sub-plates. Two ends of each of the plurality of second interconnection conductive pillars 293 may be electrically connected to the first circuit layer 292 and the second circuit layer 294 respectively. The packaging of the plurality of chips 230 and the plurality of target silicon interposer sub-plates may be completed.

The plurality of second interconnection conductive pillars 293 may be used to realize vertical electrical interconnection between the packaging structure of the plurality of chips and other chips or modules, reducing the packaging height.

In one embodiment, the second circuit layer 294 may include a dielectric layer and a metal layer. The metal layer may be formed by electroplating or directly formed by patching. In one embodiment, the second interconnect circuit layer 294 may be a microstrip antenna radiating plate. Two ends of each of the plurality of second interconnection conductive pillars 293 may be electrically connected to the metal layer in the second circuit layer 294 and the metal layer in the redistribution layer of the first circuit layer 292 respectively. By forming the second circuit layer 294 on the side of the second plastic encapsulation layer 292 away from the plurality of target silicon interposer sub-plates, the signal of the entire packaging structure may be enhanced.

The packaging structure may include the second circuit layer, and communication chips or modules may be arranged on the second circuit layer after packaging. Compared with the existing processes where a metal layer and communication chips or modules are attached after the packaging the plurality of chips, the integration level of the chip packaging may be improved.

In another embodiment shown in FIG. 42 to FIG. 47, the plurality of target silicon interposer sub-plates may include the plurality of third silicon interposer sub-plates 273, and the plurality of chips 230 may be interconnected to the plurality of target silicon interposer sub-plates through a flip-chip process.

As shown in FIG. 42, the plurality of third silicon interposer sub-plates 273 may be selected as the plurality of target silicon interposer sub-plates, and the back surfaces of the plurality of third silicon interposer sub-plates 273 may be fixed on the carrier 210. The first plastic encapsulation layer 280 may be formed on the front surfaces of the plurality of third silicon interposer sub-plates 273. The plurality of first through holes may be formed in the first plastic encapsulation layer 280 along its thickness direction, and conductive materials may be filled in the plurality of first through holes to form the plurality of first interconnection conductive pillars 281.

As shown in FIG. 43, the side of the first plastic encapsulation layer 180 away from the carrier 210 may be polished to expose the redistribution layer 222 of the plurality of third silicon interposer sub-plates 273 and the plurality of first interconnection conductive pillars 281.

As shown in FIG. 44, the first circuit layer 292 may be formed on the redistribution layer 222 of the plurality of third silicon interposer sub-plates 273.

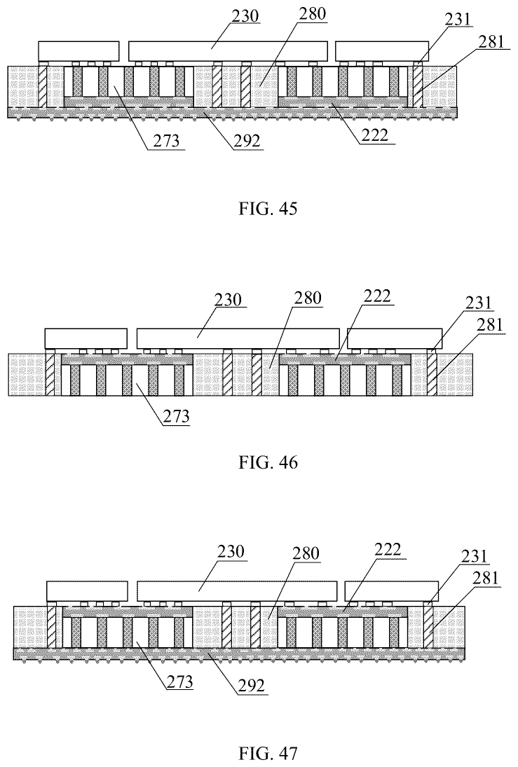

As shown in FIG. 45, the carrier 210 may be removed, and the plurality of chips 230 may be mounted on the back surfaces of the plurality of third silicon interposer sub-plates 273 through the first metal pads 231 using the flip-chip process. The first metal pads 231 may be electrically connected to the plurality of blind holes 221 filled with conductive material and the first interconnection conductive pillars 281 exposed on the back surfaces of the plurality of third silicon interposer sub-plates 273. Further, an underfill may be formed on the first metal pads 231 to further fix the plurality of chips 230 on the plurality of target silicon interposer sub-plates.

In another embodiment, as shown in FIG. 43, the side of the first plastic encapsulation layer 280 away from the carrier 210 may be ground to expose the redistribution layer 222 of the plurality of third silicon interposer sub-plates 273 and the plurality of first interconnection conductive pillars 281. As shown in FIG. 30, the plurality of chips 230 may be mounted on the front surfaces of the plurality of third silicon interposer sub-plates 273 through the first metal pads 231 using the flip-chip process. That is, the plurality of chips 230 may be mounted on the redistribution layer 222 of the plurality of third silicon interposer sub-plates 273 through the first metal pads 231 using the flip-chip process. Further, an underfill may be formed on the first metal pads 231 to further fix the plurality of chips 230 on the plurality of target silicon interposer sub-plates.

As shown in FIG. 47, after the plurality of chips 230 is mounted on the redistribution layer 222 of the plurality of third silicon interposer sub-plates 273 through the first metal pads 231 using the flip-chip process, the first circuit layer 292 may be formed on the back surfaces of the plurality of third silicon interposer sub-plates 273. The first circuit layer 292 may include a rewiring layer and solder balls, which is not specifically limited in this embodiment.

In some other embodiments, the plurality of chips 230 may be interconnected to the plurality of third silicon interposer sub-plates 273 through a hybrid bonding process. The specific hybrid bonding steps are similar to those in the previous embodiments. No further details will be given here.

In this embodiment, the plurality of chips may be interconnected to the plurality of target silicon interposer sub-plates through a flip-chip process, thereby reducing the packaging thickness and enabling ultra-thin packaging.

In another embodiment as shown in FIG. 39 to FIG. 42, the plurality of target silicon interposer sub-plates may be a combination of a plurality of second silicon interposer sub-plates 272 and a plurality of third silicon interposer sub-plates 273. Therefore, interconnecting the plurality of chips 230 to the plurality of target silicon interposer sub-plates through a hybrid bonding process may include the following processes.

As shown in FIG. 48, the front surfaces of the plurality of second silicon interposer sub-plates 272 and the front surfaces of the plurality of third silicon interposer sub-plates 273 may be fixed to a carrier 210. The first plastic encapsulation layer 280 may be formed on the back surfaces of the plurality of second silicon interposer sub-plates 272 and the back surfaces of the plurality of third silicon interposer sub-plates 273. A plurality of through holes may be formed in the first plastic encapsulation layer 280 along the thickness direction of the first plastic encapsulation layer 280, and the plurality of first through holes may be filled with conductive materials to form the plurality of first interconnection conductive pillars 281.

As shown in FIG. 49, a side of the first plastic encapsulation layer 280 away from the carrier 210 may be thinned by polishing to expose the conductive connection structures and the plurality of first interconnection conductive pillars 281 on the back surfaces of the plurality of second silicon interposer sub-plates 272 and the back surfaces of the plurality of third silicon interposer sub-plates 273.

As shown in FIG. 50, the plurality of wafers may be cut to form the plurality of different chips. In one embodiment, the plurality of heterogenous chips may be obtained. Plastic encapsulation may be performed on the plurality of chips 230 to form a second plastic encapsulation layer 291. A side of the second plastic encapsulation layer 291 facing the plurality of target silicon interposer sub-plates may be polished to expose the plurality of chips. The first metal pads 231 and the first passivation layer 232 may be sequentially formed on a side of the plurality of chips and the second plastic encapsulation layer 291.

As shown in FIG. 50, the second passivation layer 282 and the second metal pads 283 may be sequentially formed on the back surfaces of the thinned plurality of second silicon interposer sub-plates 272 and the back surfaces of the thinned plurality of third silicon interposer sub-plates 273.

As shown in FIG. 50, the first metal pads 231 and the second metal pads 283 may be bonded and connected, and the first passivation layer 232 and the second passivation layer 282 may be bonded and connected. The first metal pads 231 may also correspond to and be electrically connected to the first interconnection conductive pillars 281. Therefore, the plurality of chips 230 may be interconnected to the front surfaces of the plurality of target silicon interposer sub-plates.

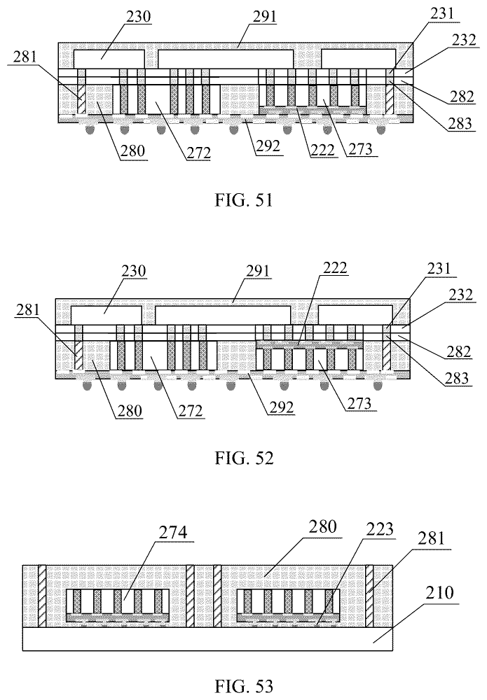

As shown in FIG. 51, after the plurality of chips 230 are interconnected to the front surfaces of the plurality of target silicon interposer sub-plates, the carrier 210 may be removed, and then a first circuit layer 292 may be formed on sides of the plurality of second silicon interposer sub-plates 272 and the plurality of third silicon interposer sub-plates 273 away from the plurality of chips. That is, the first circuit layer 292 may be formed on the front surfaces of the plurality of second silicon interposer sub-plates 272 and the plurality of third silicon interposer sub-plates 273. The packaging structure may be electrically connected to the outside world through the first circuit layer 292. The first circuit layer 292 may include a redistribution layer and soldering balls, or may also include other circuit layers, which is not specifically limited in this embodiment.

As shown in FIG. 52, in another embodiment, the back surfaces of the plurality of second silicon interposer sub-plates 272 and the plurality of third silicon interposer sub-plates 273 may be fixed to the carrier 210. Therefore, the second passivation layer 282 and the second metal pads 283 may be formed on the front surfaces of the thinned plurality of second silicon interposer sub-plates 272 and the back surfaces of the thinned plurality of third silicon interposer sub-plates 273. That is, the second passivation layer 282 and the second metal pads 283 may be formed on the silicon through holes of the plurality of second silicon interposer sub-plates 272 and the redistribution layer 292 of the plurality of third silicon interposer sub-plates 273. The plurality of chips 230 may be interconnected to the front surfaces of the plurality of second silicon interposer sub-plates 272 and the plurality of third silicon interposer sub-plates 273 through the hybrid bonding process. Subsequently, the carrier 210 may be removed, and the first circuit layer 292 may be formed on the back surfaces of the plurality of second silicon interposer sub-plates 272 and the plurality of third silicon interposer sub-plates 273.

In some other embodiments, the plurality of chips 230 may be interconnected to the plurality of target silicon interposer sub-plates through a flip-chip process or a thermal compressing/bonding process. The interconnection process may be selected according to actual needs.

In this embodiment, the plurality of chips may be interconnected to the plurality of target silicon interposer sub-plates through the hybrid bonding process, achieving high-density interconnection, improving the production efficiency, and achieving ultra-thin packaging.

In one embodiment, after forming the first circuit layer 292, the method may further include:
as shown in FIG. 41, forming a plurality of second through holes in the thickness direction of the first plastic encapsulation layer 280 and the second plastic encapsulation layer 291, to penetrate through the first plastic encapsulation layer 280 and the second plastic encapsulation layer 291. Conductive material may be filled in the plurality of second through holes to form a plurality of second interconnection conductive pillars 293. A second circuit layer 294 may be formed on a side of the second encapsulation layer 192 away from the plurality of target silicon interposer sub-plates. Two ends of each of the plurality of second interconnection conductive pillars 293 may be electrically connected to the first circuit layer 292 and the second circuit layer 294 respectively. The packaging of the plurality of chips 230 and the plurality of target silicon interposer sub-plates may be completed.

In another embodiment shown in FIG. 53 to FIG. 57, the plurality of target silicon interposer sub-plates may be fourth silicon interposer sub-plates 274. The plurality of chips 230 may be interconnected to the plurality of target silicon interposer sub-plates through a flip-chip process including following steps.

As shown in FIG. 53, the front surfaces of the plurality of fourth silicon interposer sub-plates 274 are fixed on the carrier 210. And a first plastic sealing layer 280 may be formed on the back surfaces of the plurality of fourth silicon interposer sub-plates 274. A plurality of through holes may be formed in the first plastic encapsulation layer 280 along its thickness direction, and conductive materials may be filled in the plurality of through holes to form a plurality of first interconnection conductive pillars 281.

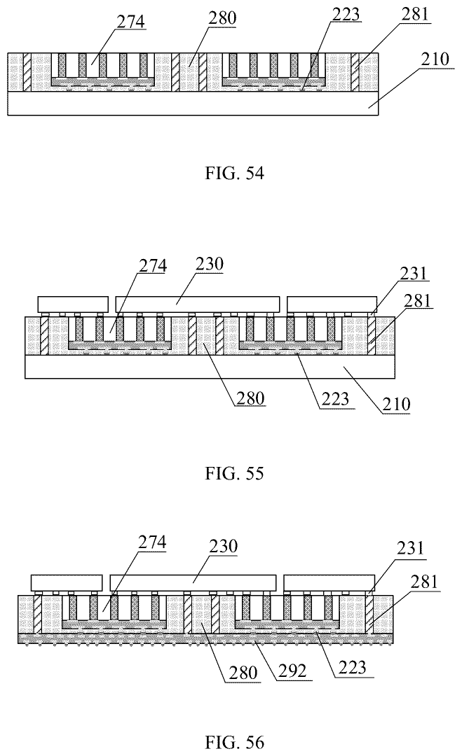

As shown in FIG. 54, the side of the first plastic encapsulation layer 280 away from the carrier 210 may be thinned through a grinding process to expose the conductive connection structures and the plurality of first interconnection conductive pillars 281 on the back surfaces of the plurality of fourth silicon interposer sub-plates 274.

As shown in FIG. 55, the plurality of chips 230 may be mounted on the back surfaces of the plurality of fourth silicon interposer sub-plates 274 through the first metal pads 231 using a flip-chip process. The first metal pads 231 may be electrically connected to the conductive connection structures and the first interconnection conductive pillars 281 exposed on the back surfaces of the plurality of fourth silicon interposer sub-plates 274 respectively.

As shown in FIG. 56, the carrier 210 may be removed, and the first circuit layer 292 may be formed on the front surfaces of the plurality of fourth silicon interposer sub-plates 274. That is, the first circuit layer 192 may be formed on the solder balls 123 of the plurality of fourth silicon interposer sub-plates 174. The first circuit layer 192 may include a rewiring layer and solder balls, which is not specifically limited in this embodiment.

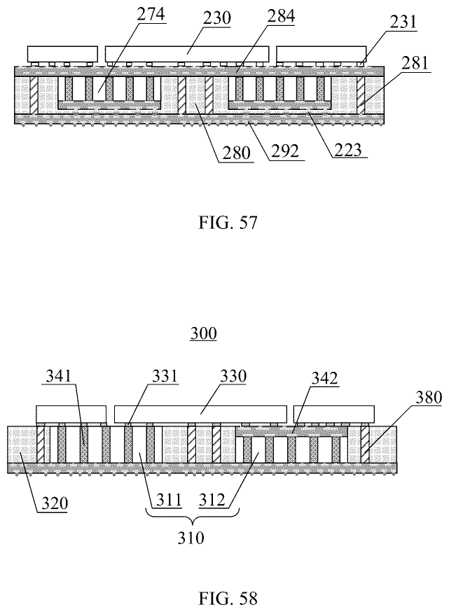

As shown in FIG. 57, after the conductive connection structures and the first interconnection conductive pillars 281 on the back surfaces of the plurality of fourth silicon interposer sub-plates 274 are exposed by thinning the side of the first plastic encapsulation layer 280 away from the carrier 210 through a grinding process, an interconnection circuit layer 284 may be formed on the conductive connection structures 274 and the first interconnection conductive pillars 281 on the back surfaces of the plurality of fourth silicon interposer sub-plates 274. Then, the plurality of chips 230 may be mounted on the interconnection circuit layer 284 on the back surfaces of the plurality of fourth silicon interposer sub-plates 274.

In some other embodiments, the plurality of chips 230 may also be interconnected to the plurality of fourth silicon interposer sub-plates 274 through a flip-chip process or a thermocompression bonding process. Those skilled in the art may select the corresponding interconnection process as needed.

In some other embodiments, the back surfaces of the plurality of fourth silicon interposer sub-plates 274 may be fixed on the carrier 210. The plurality of chips 230 may be mounted onto the solder balls 123 on the front surfaces of the plurality of fourth silicon interposer sub-plates 274 through a flip-chip process. The fixing directions of the plurality of fourth silicon interposer sub-plates 274 is not specifically limited in this embodiment and can be selected according to actual needs.

In this embodiment, the plurality of chips may be interconnected to the plurality of target silicon interposer sub-plates through a flip-chip process, thereby reducing the packaging thickness and enabling ultra-thin packaging.

In the present disclosure, the conductive connection structures may be formed on the plurality of silicon wafers to form the plurality of silicon interposer plates. The conductive connection structures on at least one silicon interposer plate may be different from the conductive connection structures on other silicon interposer plates. Each silicon interposer plate may be cut into the plurality of smaller silicon interposer sub-plates. The plurality of silicon interposer sub-plates may be reorganized according to the preset packaging requirements. The plurality of target silicon interposer sub-plates may be selected from the plurality of silicon interposer sub-plates, and the plurality of chips may be interconnected to the plurality of target silicon interposer sub-plates. Therefore, warping and cracking of the plurality of target silicon interposer plates during chip packaging may be avoided. Also, the plurality of silicon interposer plates may be cut into the plurality of smaller silicon interposer sub-plates. The plurality of silicon interposer sub-plates may be reorganized to form the plurality of target silicon interposer sub-plates which may be molded with the plurality of chips at the same time to improve the integration level of the chip packaging.

The present disclosure also provides a chip packaging structure. In one Embodiment as shown in FIG. 58 to FIG. 69, the packaging structure 300 may include a plurality of silicon interposers 310, a first plastic encapsulation layer 320, a plurality of chips 330, and a bonding structure (not shown in the figures).

Conductive connection structures may be provided on each silicon interposer 310. The conductive connection structures on at least one silicon interposer 310 may be different from the conductive connection structure on other silicon interposers 310. In one embodiment, the plurality of silicon interposers may include silicon interposers with different structures. The silicon interposers with different structures may be obtained by cutting different silicon interpose plates and the corresponding silicon interposers may be selected for combination according to actual needs.

The first plastic encapsulation layer 320 may wrap and protect the plurality of silicon interposers 310.

In one embodiment, the plurality of chips 330 may include a plurality of heterogeneous chips.

In the chip packaging structure provided by the present disclosure, the plurality of chips may be bonded and connected to the plurality of silicon interposers through a bonding structure, avoiding warping or cracking of the plurality of silicon interposers in the packaging structure. Each silicon interposer may be provided with the conductive connection structures, and the conductive connection structures on at least one silicon interposer may be different from that of other silicon interposers. That is, the structure of at least one silicon interposer may be different from other silicon interposers. Therefore, the packaging requirements of different chips may be satisfied and the integration level of chip packaging may be improved. The plurality of chips may be uniformly packaged through the plurality of different silicon interposers, which may increase the integration level of chip packaging and reduce the space occupied by chips in the packaging structure. Further, packaging different chips in a unified manner may be beneficial to save processing steps and improve packaging efficiency.

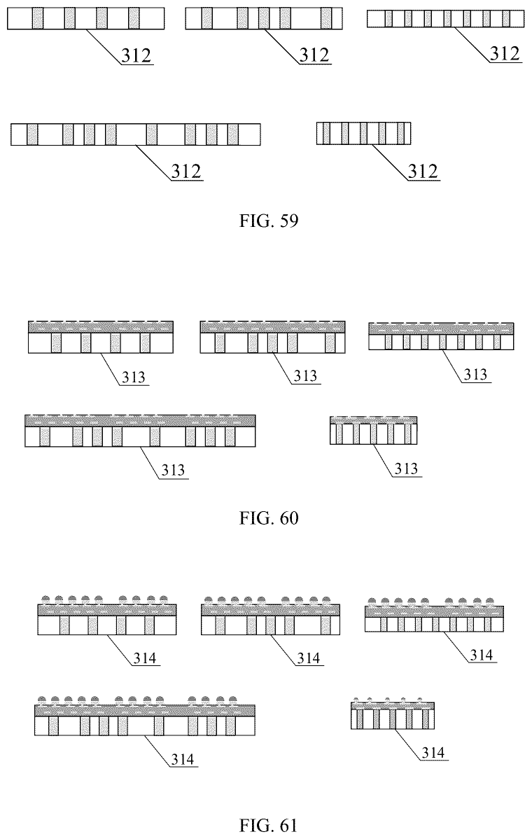

In one embodiment shown in FIG. 59, on one silicon interposer 310, the conductive connection structures may include a plurality of silicon through holes 341, and the plurality of silicon through holes 341 may be spaced apart on the silicon interposer 310. The plurality of silicon through holes 341 may be electrically connected to the bonding structure. The silicon interposer 310 whose conductive connection structures include the plurality of silicon through holes 341 may be a first silicon interposer 311.

In the above embodiment, vertical interconnection of the plurality of chips 330 may be realized through the plurality of silicon through holes 341 provided on the silicon interposer 310.

Further, in one embodiment, the plurality of silicon through holes 341 on at least one silicon interposer 310 may be different from the plurality of silicon through holes 341 on other silicon interposers 310. As shown in the figure, in this embodiment, among a plurality of first silicon interposers 311, the height, depth, width and spacing of the plurality of silicon through holes 341 in different first silicon interposers 311 may be different. That is to say, the structures of the plurality of first silicon interposers 311 may also be different.

In the above embodiment, according to the packaging requirements of the plurality of chips 130, the first silicon interposers 311 with different structures may be selected for packaging, thereby improving the integration level of the overall packaging.

In one embodiment shown in FIG. 60, on one silicon interposer 310, the conductive connection structures may include a plurality of silicon through holes 341 and a redistribution layer 342. The plurality of silicon through holes 341 may be spaced on the silicon interposer 310, and the redistribution layer 342 may be disposed on a first surface of the silicon interposer 310. The redistribution layer 342 may be electrically connected to the plurality of silicon through holes 341. One silicon interposer 310 whose conductive connection structures includes the plurality of silicon through holes 341 and the redistribution layer 342 may be a second silicon interposer 312. The first surface of the silicon interposer 310 may be the functional surface of the silicon interposer 310.

In the above embodiment, the conductive connection structures of the silicon interposer 310 may include the plurality of silicon through holes 341 and the redistribution layer 342 electrically connected to the plurality of silicon through holes 341. The plurality of silicon through holes 341 of the silicon interposer 110 may be used to achieve the vertically electrical connection of the plurality of chips 330, and the silicon interposer 310 may be electrically connected to the plurality of chips 330 through the redistribution layer 342, which improves the flexibility of packaging and integration. The redistribution layer 342 may also increase the interconnection density between the silicon interposer 310 and the plurality of chips 330.

Further, the plurality of silicon through holes 341 on at least one silicon interposer 310 may be different from the plurality of silicon through holes 341 on other silicon interposers 310. As shown in the figure, in this embodiment, among a plurality of second silicon interposers 312, the height, depth, width and spacing of the plurality of silicon through holes 341 in different second silicon interposers 312 may be different. That is, the structures of the plurality of second silicon interposers 312 may also be different.

In the above embodiment, according to the packaging requirements of the plurality of chips 330, the second silicon interposers 312 with different structures may be selected for packaging, thereby improving the integration level of the overall packaging.

In one embodiment shown in FIG. 61, on one silicon interposer 310, the conductive connection structures may include a plurality of silicon through holes 341, a redistribution layer 342, and a plurality of soldering balls 343. The plurality of silicon through holes 341 may be spaced on the silicon interposer 310, and the redistribution layer 342 may be disposed on a first surface of the silicon interposer 310. The redistribution layer 342 may be electrically connected to the plurality of silicon through holes 341. The plurality of soldering balls 343 may be disposed on and electrically connected to the redistribution layer 342. One silicon interposer 310 whose conductive connection structures includes the plurality of silicon through holes 341, the redistribution layer 342 and the plurality of soldering balls 343 may be a third silicon interposer 313. The first surface of the silicon interposer 310 may be the functional surface of the silicon interposer 310.

In the above embodiment, the conductive connection structures of the silicon interposer 310 may include the plurality of silicon through holes 341, the redistribution layer 342, and the plurality of soldering balls 343. The plurality of silicon through holes 341 of the silicon interposer 110 may be used to achieve the vertically electrical connection of the plurality of chips 330, and the silicon interposer 310 may be electrically connected to the plurality of chips 330 through the redistribution layer 342, increasing the interconnection density between the silicon interposer 310 and the plurality of chips 330. The silicon interposer 310 may be connected to the plurality of chips 330 or the outside world through the plurality of soldering balls, increasing the strength of transmitting signals.

Further, the plurality of silicon through holes 341 on at least one silicon interposer 310 may be different from the plurality of silicon through holes 341 on other silicon interposers 310. As shown in the figure, in this embodiment, among a plurality of third silicon interposers 313, the height, depth, width and spacing of the plurality of silicon through holes 341 in different third silicon interposers 313 may be different. That is, the structures of the plurality of third silicon interposers 313 may also be different.

In the above embodiment, according to the packaging requirements of the plurality of chips 330, the third silicon interposers 313 with different structures may be selected for packaging, thereby improving the integration level of the overall packaging.

The plurality of silicon interposers 310 may include a same type of silicon interposers or different types of silicon interposers. That is, in some embodiments, the plurality of silicon interposers 310 may include at least two of the first silicon interposers 311, the second silicon interposers 312, and the third silicon interposers 313. In some other embodiments, the same types of silicon interposers may be selected, while the conductive connection structures on the silicon interposers 310 of the same type may be different. For example, the plurality of silicon interposers 310 may be the plurality of first silicon interposers 311, but the plurality of silicon through holes 341 in each first silicon interposer 311 may be different. As shown in the figure, the spacing, depth and width of the plurality of silicon through holes 341 in different first silicon interposers 311 may be different. In other words, only the structures of the plurality of silicon interposers 310 may need to be different.

Each silicon interposer may be provided with the conductive connection structures, and the conductive connection structures on at least one silicon interposer may be different from that of other silicon interposers. That is, the structure of at least one silicon interposer may be different from other silicon interposers. Therefore, according to the packaging requirements and chip types, different silicon interposers may be used to connect the chips. Therefore, the packaging requirements of different chips may be satisfied and the integration level of chip packaging may be improved.

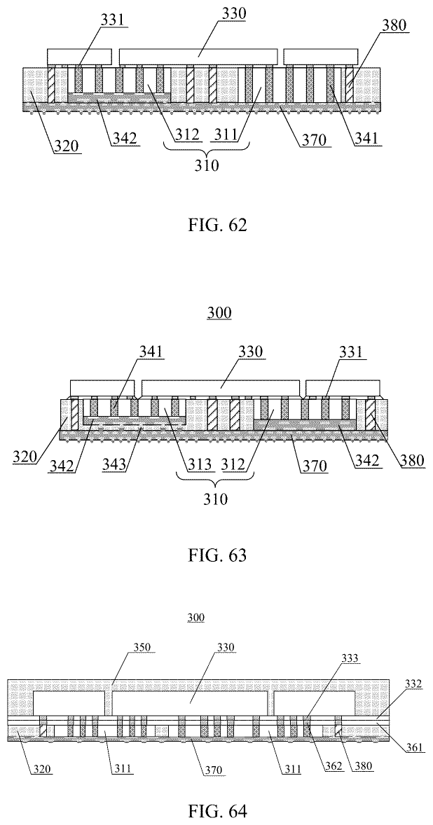

In one embodiment as shown in FIG. 58, FIG. 62, and FIG. 63, the bonding structure may include conductive pillars 331 on a side of the plurality of chips 330 facing the plurality of silicon interposers 310. In one embodiment, the plurality of conductive pillars 331 may be copper pillars.

The plurality of chips 330 may be mounted on a side of the plurality of silicon interposers 310 facing the plurality of chips 330 through the plurality of conductive pillars 331 using a flip-chip process.

As shown in FIG. 58, in one embodiment, a plurality of first silicon interposers 311 and a plurality of second silicon interposers 312 may be selected for bonding and connection with the plurality of chips 330. The heights of the plurality of first silicon interposers 311 and the plurality of second silicon interposers 312 may be the same. As shown in FIG. 1, the first surfaces of the second silicon interposers 312 may be disposed toward the plurality of chips 330. That is, the plurality of chips 330 may be bonded and connected to the first surfaces of the plurality of second silicon interposers 312. Since the conductive connection structures on the first silicon interposers 11 only include the plurality of silicon through holes 341, the bonding and connections between the plurality of the plurality of chips 330 and the first surfaces or the second surfaces of the first silicon interposers 311 may be the same, and may include the plurality of conductive pillars 331 electrically connected to the plurality of silicon through holes 341.

In this embodiment, the plurality of chips 330 may be mounted on the side of the plurality of first silicon interposers 311 and the side of the plurality of second silicon interposers 312 facing the plurality of chips 330 through the plurality of conductive pillars 331 using a flip-chip process. The plurality of conductive pillars 331 of the plurality of chips 330 may correspond to and be electrically connected to the plurality of silicon through holes 341 on the plurality of first silicon interposers 311, and the plurality of conductive pillars 331 of the plurality of chips 330 may be electrically connected to the redistribution layer 342 on the plurality of second silicon interposers 312.

As shown in FIG. 62, in another embodiment, a plurality of first silicon interposers 311 and a plurality of second silicon interposers 312 may be selected for bonding and connection with the plurality of chips 330. The heights of the plurality of first silicon interposers 311 and the plurality of second silicon interposers 312 may be the same. The first surfaces of the second silicon interposers 312 may be disposed away from the plurality of chips 330. That is, the plurality of chips 330 may be bonded and connected to the second surfaces of the plurality of second silicon interposers 312.

In this embodiment, the plurality of chips 330 may be mounted on the side of the plurality of first silicon interposers 311 and the side of the plurality of second silicon interposers 312 facing the plurality of chips 330 through the plurality of conductive pillars 331 using a flip-chip process. The plurality of conductive pillars 331 of the plurality of chips 330 may correspond to and be electrically connected to the plurality of silicon through holes 341 on the plurality of first silicon interposers 311, and the plurality of conductive pillars 331 of the plurality of chips 330 may correspond to and be electrically connected to the plurality of silicon through holes 341 on the plurality of second silicon interposers 312.

As shown in FIG. 63, in another embodiment, a plurality of second silicon interposers 312 and a plurality of third silicon interposers 313 may be selected for bonding and connection with the plurality of chips 330. The heights of the plurality of second silicon interposers 312 and the plurality of third silicon interposers 313 may be the same. The first surfaces of the second silicon interposers 312 and the first surfaces of the third silicon interposers 313 may be disposed away from the plurality of chips 330. That is, the plurality of chips 330 may be bonded and connected to the second surfaces of the plurality of second silicon interposers 312 and the second surfaces of the plurality of third silicon interposers 313 respectively.

In this embodiment, the plurality of chips 330 may be mounted on the side of the plurality of second silicon interposers 312 and the side of the plurality of third silicon interposers 313 facing the plurality of chips 330 through the plurality of conductive pillars 331 using a flip-chip process. The plurality of conductive pillars 331 of the plurality of chips 330 may correspond to and be electrically connected to the plurality of silicon through holes 341 on the second surfaces of the plurality of first silicon interposers 311, and the plurality of conductive pillars 331 of the plurality of chips 330 may correspond to and be electrically connected to the plurality of silicon through holes 341 on the second surfaces of the plurality of second silicon interposers 312.

In some other embodiments, the plurality of chips 330 may be mounted on the first surfaces of the plurality of second silicon interposers 312 and the first surfaces of the plurality of third silicon interposers 313 using a flip-chip process. The plurality of conductive pillars 331 of the plurality of chips 330 may be electrically connected to the redistribution layer on the second surfaces of the plurality of first silicon interposers 311, and the plurality of conductive pillars 331 of the plurality of chips 330 may correspond to and be electrically connected to the plurality of soldering balls 343 on the first surfaces of the plurality of second silicon interposers 312.

In some embodiments, the packaging structure 300 may further include an underfill layer (not labelled in the figure). The underfill layer may wrap the plurality of conductive pillars 331 to protect the plurality of conductive pillars 331, to further fix the plurality of chips 330 on the plurality of silicon interposers 310.

The plurality of 330 may be mounted on the first or second surfaces of the plurality of silicon interposers 310 through the plurality of conductive pillars 331 using a flip-chip process, which may be selected according to specific packaging requirements, thereby increasing the integration level of the packaging.

In the above embodiments, the plurality of chips may be mounted on the side of the plurality of silicon interposers facing the plurality of chips through the plurality of conductive pillars, thereby reducing the packaging thickness and enabling ultra-thin packaging.

In some other embodiments, other types of silicon interposers may be selected and combined to be bonded to the plurality of chips.

In one embodiment as shown in FIG. 64 to FIG. 69, the packaging structure 300 may further include a second plastic encapsulation layer 350. The second plastic encapsulation layer 350 may wrap and protect the plurality of chips 330.

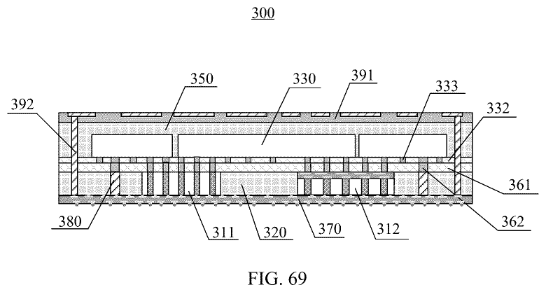

As shown in FIG. 64, to FIG. 66 and FIG. 69, the bonding structure may further include first passivation layers 332 and first metal pads 333 disposed on a side of the plurality of chips 330 and a side of the second plastic encapsulation layer 350 facing the plurality of silicon interposers 310, and second passivation layers 361 and second metal pads 362 disposed on a side of the plurality of silicon interposers 310 and a side of the first plastic encapsulation layer 320 facing the plurality of chips 330.

The second passivation layers 361 and the first passivation layers 332 may be bonded and connected, and the second metal pads 62 and the first metal pads 333 may be bonded and connected. That is, the bonding structure may be a hybrid bonding structure, and the plurality of chips 330 may be hybridly bonded and connected to the plurality of silicon interposers 310 through the hybrid bonding structure.

The first passivation layers 332 and the second passivation layers 361 may be a silicon dioxide passivation layer or a silicon nitride layer, or other materials that can play a passivation role, which is not limited in this embodiment. The first metal pad 333 and the second metal pads 362 may be made of a material including metal copper or other metal materials, which is not specifically limited in this embodiment.

As shown in FIG. 64, in one embodiment, a plurality of first silicon interposers 311 may be selected for hybrid bonding and connection with the plurality of chips 330. The structures of the plurality of first silicon interposers 311 may be different, and the heights of the plurality of first silicon interposers 311 may be the same. For example, the spacing density and width of the silicon through holes 341 on different first silicon interposers 311 may be different. The second metal pads 362 may correspond to and be electrically connected to the silicon through holes 341 on the first silicon interposers 311.

In the above embodiments, different silicon interposers may be selected to meet the packaging requirements of different chips, thereby increasing the integration level of the overall packaging.

In this embodiment, the plurality of chips 330 may be hybrid-bonded and connected to the plurality of first silicon interposers 311 through a hybrid bonding structure. The first passivation layers 332 and the first metal pads 333 may be provided on the sides of the plurality of chips 330 and the second plastic encapsulation layer 350 facing the plurality of first silicon interposers 311. The second passivation layers 361 and the second metal pads 362 may be provided on the first surface or the second surface of the plurality of silicon interposers 311 and the first plastic encapsulation layer 320. The second passivation layers 361 and the first passivation layers 332 may be bonded and connected, and the second metal pads 62 and the first metal pads 333 may be bonded and connected. Therefore, the plurality of chips 330 may be disposed on the plurality of silicon interposers 311.

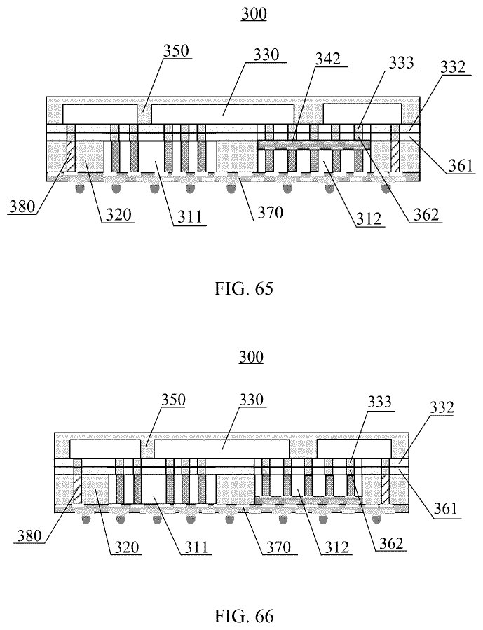

As shown in FIG. 65, in another embodiment, a plurality of first silicon interposers 311 and a plurality of second silicon interposers 312 may be selected for hybrid bonding and connection with the plurality of chips 330. The heights of the plurality of first silicon interposers 311 and the plurality of second silicon interposers 312 may be the same.

The first passivation layers 332 and the first metal pads 333 may be provided on the sides of the plurality of chips 330 and the second plastic encapsulation layer 350 facing the plurality of first silicon interposers 311. The second passivation layers 361 and the second metal pads 362 may be provided on the first surfaces of the plurality of first silicon interposers 311, the first surfaces of the plurality of second silicon interposers 312, and the surface of the first plastic encapsulation layer 320 facing the plurality of chips 330. That is, the second passivation layers 361 and the second metal pads 362 may be disposed on the plurality of silicon through holes 341 of the plurality of first silicon interposers 311 and on the redistribution layer 342 of the plurality of second silicon interposers 312. The second metal pads 62 may correspond to and electrically connected to the plurality of silicon through holes 341 on the plurality of first silicon interposers 311 and the plurality of second silicon interposers 312. The second passivation layers 361 and the first passivation layers 332 may be bonded and connected, and the second metal pads 62 and the first metal pads 333 may be bonded and connected. Therefore, the plurality of chips 330 may be disposed on the first surfaces of the plurality of first silicon interposers 311 and the first surfaces of the plurality of second silicon interposers 312.

As shown in FIG. 66, in another embodiment, a plurality of first silicon interposers 311 and a plurality of second silicon interposers 312 may be selected for hybrid bonding and connection with the plurality of chips 330. The heights of the plurality of first silicon interposers 311 and the plurality of second silicon interposers 312 may be the same.

The first passivation layers 332 and the first metal pads 333 may be provided on the sides of the plurality of chips 330 and the second plastic encapsulation layer 350 facing the plurality of first silicon interposers 311. The second passivation layers 361 and the second metal pads 362 may be provided on the second surfaces of the plurality of first silicon interposers 311, the second surfaces of the plurality of second silicon interposers 312, and the surface of the first plastic encapsulation layer 320 facing the plurality of chips 330. That is, the second passivation layers 361 and the second metal pads 362 may be disposed on the plurality of silicon through holes 341 of the plurality of first silicon interposers 311 and on the plurality of silicon through holes 341 of the plurality of second silicon interposers 312. The second metal pads 62 may correspond to and electrically connected to the plurality of silicon through holes 341 on the plurality of first silicon interposers 311 and the plurality of second silicon interposers 312. The second passivation layers 361 and the first passivation layers 332 may be bonded and connected, and the second metal pads 62 and the first metal pads 333 may be bonded and connected. Therefore, the plurality of chips 330 may be disposed on the second surfaces of the plurality of first silicon interposers 311 and the second surfaces of the plurality of second silicon interposers 312.

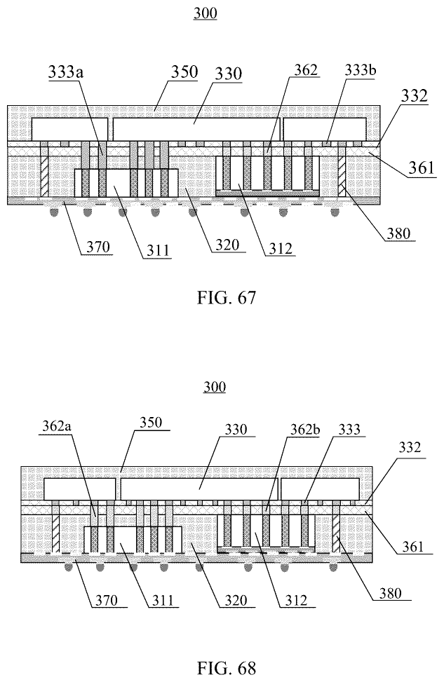

As shown in FIG. 67, in another embodiment, a plurality of first silicon interposers 311 and a plurality of second silicon interposers 312 may be selected for hybrid bonding and connection with the plurality of chips 330. The heights of the plurality of first silicon interposers 311 may be smaller than the heights of the plurality of second silicon interposers 312.

The first passivation layers 332 may be provided on the sides of the plurality of chips 330 and the second plastic encapsulation layer 350 facing the plurality of first silicon interposers 311, and first metal sub-pads 333a may be disposed on the positions corresponding to the plurality of first interposers 311 and the second metal sub-pads 333b may be disposed at the positions corresponding to the plurality of second silicon interposers 312. The length of the first metal sub-pads 333a may be larger than the length of the second metal sub-pads 333b. The second passivation layers 361 may be provided on the second surfaces of the plurality of second silicon interposers 312 and the surface of the first plastic encapsulation layer 320 facing the plurality of chips 330. The second metal pads 352 may be disposed on the second surfaces of the plurality of second silicon interposers 312. A plurality of grooves may be formed in the second passivation layer 361 and the first plastic encapsulation layer 320 corresponding to the plurality of first silicon interposers 311. The depth of the plurality of grooves may be same as the length of the first metal sub-pads 333a.

The second passivation layers 361 and the first passivation layers 332 may be bonded and connected. The first metal sub-pads 333a may be inserted into corresponding grooves, and the second metal pads 362 and the second metal sub-pads 333b may be bonded and connected. Therefore, the plurality of chips 330 may be disposed on the second surfaces of the plurality of first silicon interposers 311 and the second surfaces of the plurality of second silicon interposers 312.

As shown in FIG. 68, in another embodiment, a plurality of first silicon interposers 311 and a plurality of second silicon interposers 312 may be selected for hybrid bonding and connection with the plurality of chips 330. The heights of the plurality of first silicon interposers 311 may be smaller than the heights of the plurality of second silicon interposers 312.

The first passivation layers 332 and the first metal pads 333 may be provided on the sides of the plurality of chips 330 and the second plastic encapsulation layer 350 facing the plurality of first silicon interposers 311. The second passivation layers 361 may be provided on the second surfaces of the plurality of second silicon interposers 312 and the surface of the first plastic encapsulation layer 320 facing the plurality of chips 330. The third metal sub-pads 362 may be provided on the surfaces of the plurality of first silicon interposers 311 facing the plurality of chips 330, and a fourth metal sub-pads 362b may be provided on the second surfaces of the plurality of second silicon interposers 312. The length of the third metal sub-pads 362a may be greater than the length of the fourth s metal sub-pads 362b, and the upper surfaces of the third metal sub-pads 362a and the fourth metal sub-pads 362b may be flush.

The second passivation layers 361 and the first passivation layers 332 may be bonded and connected. The first metal pads 333 may be bonded and connected to the third metal sub-pads 362a and the fourth metal sub-pads 362b respectively.

As shown in FIG. 58, FIG. 62 to FIG. 69, in one embodiment, the packaging structure 300 may further include a first circuit layer 370. The first circuit layer 370 may be disposed on a side of the plurality of silicon interposers 310 away from the plurality of chips 330. In this embodiment, the first circuit layer 370 may be disposed on the first surface or the second surface of the plurality of chips 330, which can be selected according to actual requirements. The packaging structure 300 may be electrically connected to the outside world through the first circuit layer 370. The first circuit layer 370 may include a rewiring layer and solder balls, or may include other circuit layers, which is not specifically limited in this embodiment.

In one embodiment shown in FIG. 58, the first circuit layer 370 may be formed on the second surfaces of the plurality of first silicon interposers 311 and the plurality of second silicon interposers 312. In another embodiment shown in FIG. 5, the first circuit layer 370 may be formed on the first surfaces of t the plurality of first silicon interposers 311 and the plurality of second silicon interposers 312. In another embodiment shown in FIG. 6, the first circuit layer 370 may be formed on the first surfaces of the plurality of second silicon interposers 312 and the plurality of third silicon interposers 313. In another embodiment shown in FIG. 8, the first circuit layer 370 may be formed on the second surface of the plurality of first silicon interposers 311 and the plurality of second silicon interposers 312. In another embodiment shown in FIG. 9, the first circuit layer 370 may be formed on the first surfaces of the plurality of first silicon interposers 311 and the plurality of second silicon interposers 312.

In one embodiment, as shown in FIG. 58 and FIG. 62 to FIG. 69, the packaging structure 300 may further include a plurality of first interconnection conductive pillars 380. The plurality of first interconnection conductive pillars 380 may penetrate through the thickness of the first plastic encapsulation layer 320 and may be distributed in the first plastic encapsulation layer 320 at intervals. Two ends of each first interconnection conductive pillar 380 may be electrically connected to the plurality of chips 330 and the first circuit layer 370 respectively.

In the above embodiments, the plurality of first interconnection conductive pillars may be used to realize vertical electrical interconnection between the plurality of chips and the first circuit layer, thereby reducing the packaging height.

In one embodiment, as shown in FIG. 69, the packaging structure 300 may further include a second circuit layer 391 and a plurality of second interconnection conductive pillars 392. The second circuit layer 391 may be disposed on the side of the second plastic encapsulation layer 350 away from the plurality of chips 330.

The plurality of second interconnection conductive pillars 392 may penetrate through the thickness of the first plastic encapsulation layer 320, the bonding structure and the second plastic encapsulation layer 350, and may be distributed in the first plastic encapsulation layer 320 and the second plastic encapsulation layer 350 at intervals. Two ends of each second interconnection conductive pillar 392 may be electrically connected to the first circuit layer 370 and the second circuit layer 391 respectively.

In this embodiment, the plurality of second interconnection conductive pillars 392 may be used to realize vertical electrical interconnection between the chip packaging structure 300 and other chips or modules, and reduce the packaging height.

The second circuit layer 391 may include a dielectric layer and a metal layer, where the metal layer may be formed by electroplating or directly formed by patching. In one embodiment, the second circuit layer 391 may be a microstrip antenna radiation piece. Both ends of the plurality of second interconnection conductive pillars 392 may be electrically connected to the metal layer in the second circuit layer 391 and the metal layer in the rewiring layer of the first circuit layer 370 respectively. The second circuit layer 391 may be formed on the side of the second plastic encapsulation layer 350 away from the plurality of target sub-silicon interposers. The second circuit layer 391 may be electrically connected to chips or modules outside the packaging structure 300, to enhance the signal throughout the package structure.

The packaging structure may include the second circuit layer, and communication heterogeneous chips or modules may be arranged on the second circuit layer after packaging. Compared with the existing heterogeneous chips that are packaged and then attached with metal layers and communication heterogeneous modules, the integration of heterogeneous chip packaging may be improved.

In the present disclosure, each wafer may be cut to form the plurality of heterogeneous chips. The plurality of target heterogeneous chips may be selected from the plurality of heterogeneous chips to form the chipsets, and the chipsets may be bonded to the silicon interposer plate. Warping or cracking of the silicon interposer plate when thinning the silicon interposer plate after interconnecting the chipsets to the silicon interposer plate may be avoided. By cutting the plurality of wafers to form the plurality of heterogeneous chips and selecting the plurality of target heterogeneous chips from the plurality of heterogeneous chips to reorganize to form the chipsets. The reorganized chipsets may be molded together with the silicon interposer plate at one time, thereby improving the overall integration of the chip package.

In the present disclosure, the plurality of heterogeneous chips may be molded with the silicon interposer plate at one time through the bonding structure, thereby improving the overall integration of the chip package. The first plastic encapsulation layer may wrap the plurality of heterogeneous chips and then may be bonded and connected with the silicon interposer plate, to avoid warping or cracking of the silicon interposer plate during the bonding and connection process.

In the present disclosure, the plurality of blind holes formed on the front surface of at least one silicon wafer may be different from the plurality of blind holes formed on the front surfaces of the remaining silicon wafers. Therefore, the conductive connection structures with different integration levels may be formed, improving the overall integration level of the packaging.

In the present disclosure, according to the preset packaging requirements, the plurality of target silicon interposer sub-plates may be selected from the plurality of silicon interposer sub-plates, and the plurality of target silicon interposer sub-plates may be fixed to the carrier board. Therefore, warping or cracking of the silicon interposers may be avoided when the plurality of chips is bonded to the plurality of target silicon interposer sub-plates. The conductive connection structures of at least one of the plurality of target silicon interposer sub-plates may be different from the conductive connection structures of others of the plurality of target silicon interposer sub-plates. The reorganized silicon interposer sub-plates may be formed with the plurality of chips at one time, thereby improving the integration level of chip packaging.

In the present disclosure, according to the preset packaging requirements, the plurality of target silicon interposer sub-plates may be selected from the plurality of silicon interposer sub-plates, and the plurality of target silicon interposer sub-plates may be fixed to the carrier board. Therefore, warping or cracking of the silicon interposers may be avoided when the plurality of chips is bonded to the plurality of target silicon interposer sub-plates. The conductive connection structures of at least one of the plurality of target silicon interposer sub-plates may be different from the conductive connection structures of others of the plurality of target silicon interposer sub-plates. The reorganized silicon interposer sub-plates may be formed with the plurality of chips at one time, thereby improving the integration level of chip packaging.

In the present disclosure, the drawings and descriptions of the embodiments are illustrative and not restrictive. The same drawing reference numerals identify the same structures throughout the description of the embodiments. In addition, figures may exaggerate the thickness of some layers, films, screens, areas, etc., for purposes of understanding and ease of description. It will also be understood that when an element such as a layer, film, region or substrate is referred to as being “on” another element, it may be directly on the another element or intervening elements may be present. In addition, “on” refers to positioning an element on or below another element, but does not essentially mean positioning on the upper side of another element according to the direction of gravity.

The orientation or positional relationship indicated by the terms “upper,” “lower,” “top,” “bottom,” “inner,” “outer,” etc. are based on the orientation or positional relationship shown in the drawings, and are only for the convenience of describing the present disclosure, rather than indicating or implying that the device or element referred to must have a specific orientation, be constructed and operated in a specific orientation, and therefore cannot be construed as a limitation of the present disclosure. When a component is said to be “connected” to another component, it may be directly connected to the other component or there may be an intermediate component present at the same time.

It should also be noted that in this article, relational terms such as “first” and “second” are only used to distinguish one entity or operation from another entity or operation, and do not necessarily require or imply that there is such actual relationship or sequence between these entities or operations them. Furthermore, the terms “comprises,” “includes,” or any other variation thereof are intended to cover a non-exclusive inclusion, such that an article or device including a list of elements includes not only those elements, but also other elements not expressly listed. Or it also includes elements inherent to the article or equipment. Without further limitation, an element defined by the statement “comprises a . . . ” does not exclude the presence of other identical elements in an article or device that includes the above-mentioned element.

The embodiments disclosed herein are exemplary only. Other applications, advantages, alternations, modifications, or equivalents to the disclosed embodiments are obvious to those skilled in the art and are intended to be encompassed within the scope of the present disclosure.

What is claimed is:

1. A chip packaging method, comprising:
providing a carrier and a plurality of wafers, wherein at least one of the plurality of wafers is different from other wafers of the plurality of wafers;
cutting each of the plurality of wafers respectively, to form a plurality of chips;
selecting a plurality of target chips from the plurality of chips to form chipsets, and fixing functional surfaces of the chipsets to the carrier;
forming a first plastic encapsulation layer on a side of the chipsets away from the carrier and removing the carrier;
forming silicon interposer plates and bonding the silicon interposer plates to the chipsets;
cutting the silicon interposer plates and the chipsets after bonding to form a plurality of chip micro-modules, wherein each of the plurality of chip micro-modules includes one of the chipsets;
fixing a side of the silicon interposer plates in the plurality of chip micro-modules to the carrier and forming a second plastic encapsulation layer on a side of the plurality of chip micro-modules away from the carrier; and
removing the carrier and cutting the second plastic encapsulation layer, to form independent packaging structures.

2. The method according to claim 1, wherein forming the silicon interposer plates includes:
providing silicon wafers and forming blind holes distributed at intervals on front surfaces of the silicon wafers;
filling the blind holes with conductive materials to form a plurality of conductive connection structures;
forming a first redistribution layer on the front surfaces of the silicon wafer to form the silicon interposer plates, where the first redistribution layer is electrically connected to the plurality of conductive connection structures.

3. The method according to claim 2, wherein bonding the silicon interposer plates to the chipsets includes:
forming first metal pads and a first passivation layer on the functional surfaces of the chipsets and the first plastic encapsulation layer;
forming second metal pads and a second passivation layer on the first redistribution layer; and
bonding the second metal pads to the first metal pads, and bonding the second passivation layer to the first passivation layer.

4. The method according to claim 1, after bonding the silicon interposer plates to the chipsets, further including:
thinning s side of the first plastic encapsulation layer away from the silicon interposer plates to expose non-functional surfaces of the chipsets; and
thinning a side of the silicon interposers away from the chipsets to expose the plurality of conductive connection structures.

5. The method according to claim 1, wherein cutting the silicon interposer plates and the chipsets after bonding to form the plurality of chip micro-modules includes:
cutting and removing a portion of the first plastic encapsulation layer at edge areas of each chipset in each chip micro-module, such that the edge areas of the chipset is flush with edge areas of the silicon interposer plates.

6. The method according to claim 1, after cutting the second plastic encapsulation layer, further including:
forming a second redistribution layer on a side of the silicon interposer plates away from the chipsets; and
forming a plurality of soldering balls on the second redistribution layer to form the independent packaging structures.

7. A chip packaging method, comprising:
providing a carrier, a plurality of silicon wafers, and a plurality of chips;
forming conductive connection structures on the plurality of silicon wafers respectively to form a plurality of silicon interposer plates; wherein the conductive connection structures on at least one of the plurality of silicon interposer plates is different from the conductive connection structures on others of the plurality of silicon interposer plates;
cutting each of the plurality of silicon interposer plates respectively to obtain a plurality of silicon interposer sub-plates;
selecting a plurality of target silicon interposer sub-plates from the plurality of silicon interposer sub-plates according to preset packaging requirements, and fixing the plurality of target silicon interposer sub-plate to the carrier;
forming a first plastic encapsulation layer on a side of the plurality of silicon interposer sub-plates away from the carrier; and
interconnecting the plurality of chips to the plurality of target silicon interposer sub-plates respectively.

8. The method according to claim 7, wherein:
when selecting the plurality of target silicon interposer sub-plates from the plurality of silicon interposer sub-plates according to the preset packaging requirements and fixing the plurality of target silicon interposer sub-plate to the carrier, the conductive connection structures on at least one of the plurality of target silicon interposer sub-plates is different from the conductive connection structures on others of the plurality of target silicon interposer sub-plates.

9. The method according to claim 7, wherein:
forming the conductive connection structures on the plurality of silicon wafers respectively includes:
forming a plurality of blind holes on a front surface of at least one of the plurality of silicon wafers, wherein the plurality of blind holes on at least one of the plurality of silicon wafers is different from the plurality of blind holes on others of the plurality of silicon wafers; and
filling the plurality of blind holes with conductive materials to form the conductive connection structures.

10. The method according to claim 7, wherein forming the conductive connection structures on the plurality of silicon wafers respectively includes:
forming a plurality of blind holes on a front surface of at least one of the plurality of silicon wafers, wherein the plurality of blind holes on at least one of the plurality of silicon wafers is different from the plurality of blind holes on others of the plurality of silicon wafers;
filling the plurality of blind holes with conductive materials; and
thinning back surfaces of the plurality of silicon wafers until exposing the plurality of blind holes to form the conductive connection structures.

11. The method according to claim 7, wherein forming the conductive connection structures on the plurality of silicon wafers respectively includes:
forming a plurality of blind holes on a front surface of at least one of the plurality of silicon wafers, wherein the plurality of blind holes on at least one of the plurality of silicon wafers is different from the plurality of blind holes on others of the plurality of silicon wafers;
filling the plurality of blind holes with conductive materials;
forming a redistribution layer on the plurality of blind holes; and
thinning back surfaces of the plurality of silicon wafers until exposing the plurality of blind holes to form the conductive connection structures.

12. The method according to claim 7, wherein forming the conductive connection structures on the plurality of silicon wafers respectively includes:
forming a plurality of blind holes on a front surface of at least one of the plurality of silicon wafers, wherein the plurality of blind holes on at least one of the plurality of silicon wafers is different from the plurality of blind holes on others of the plurality of silicon wafers;
filling the plurality of blind holes with conductive materials;
forming a redistribution layer on the plurality of blind holes;
forming a plurality of soldering balls on the redistribution layer; and
thinning back surfaces of the plurality of silicon wafers until exposing the plurality of blind holes to form the conductive connection structures.

13. The method according to claim 7, wherein:
interconnecting the plurality of chips to the plurality of target silicon interposer sub-plates respectively includes: forming a second plastic encapsulation layer on a side of the plurality of chips away from the plurality of target silicon interposer sub-plates; interconnecting a side of the plurality of chips and the second plastic encapsulation layer facing the plurality of target silicon interposer sub-plates to a side of the plurality of target silicon interposer sub-plates facing the plurality of chips through a bonding structure; and
after interconnecting the plurality of chips to the plurality of target silicon interposer sub-plates respectively, the method further includes: forming a first circuit layer on a side of the plurality of target silicon interposer sub-plates away from the plurality of chips.

14. The method according to claim 13, wherein, after forming the first plastic encapsulation layer on the side of the plurality of silicon interposer sub-plates away from the carrier or after interconnecting the plurality of chips to the plurality of target silicon interposer sub-plates respectively, further comprising:
forming a plurality of through holes in the first plastic encapsulation layer along the thickness direction of the first plastic encapsulation layer, and filling the plurality of through holes with conductive materials to form a plurality of first interconnection conductive pillars, wherein two ends of each of the plurality of first interconnection conductive pillars are electrically connected to the plurality of chips and the first circuit layer respectively.

15. The method according to claim 14, wherein, forming the first circuit layer on the side of the plurality of target silicon interposer sub-plates away from the plurality of chips, further comprising:
forming a plurality of second through holes penetrating through the thickness direction of the first plastic encapsulation layer and the second plastic encapsulation layer; and
filling the plurality of second through holes with conductive materials to form a plurality of second interconnection conductive pillars.

16. The method according to claim 14, wherein, forming the first circuit layer on the side of the plurality of target silicon interposer sub-plates away from the plurality of chips, further comprising:
forming a second circuit layer on a side of the second plastic encapsulation layer away from the plurality of target silicon interposer sub-plates, wherein two ends of each of the plurality of second interconnection conductive pillars are electrically connected to the first circuit layer and the second circuit layer respectively.

17. A chip packaging structure, comprising a plurality of chips, a silicon interposer, a bonding structure, a first plastic encapsulation layer, and a second plastic encapsulation layer, wherein:
the plurality of chips is bonded and connected to the silicon interposer through the bonding structure;
the first plastic encapsulation layer wraps the plurality of chips; and
the second plastic encapsulation layer wraps the silicon interposer, the plurality of chips and the first plastic encapsulation layer.

18. The chip packaging structure according to claim 17, wherein:
the silicon interposer is provided with a plurality of conductive connection structures distributed at intervals;
a first redistribution layer is disposed on a side of the plurality of conductive connection structures facing the plurality of chips; and
the first redistribution layer is electrically connected to the plurality of conductive connection structures.

19. The chip packaging structure according to claim 18, wherein:
the bonding structure includes first metal pads and a first passivation layer disposed on a side of the plurality of chips and a side of the first plastic encapsulation layer facing the silicon interposer, and second metal pads and a second passivation layer disposed on a side of the first redistribution layer facing the plurality of chips; and
the second metal pads are bonded and connected to the first metal pads, and the second passivation layer is bonded and connected to the first passivation layer.

20. The chip packaging structure according to claim 18, further including a second redistribution layer and a plurality of soldering balls, wherein:
the second redistribution layer is disposed on a side of the silicon interposer away from the plurality of chips; and
the plurality of solder balls is disposed on the second redistribution layer.
